(19) United States
(12) Patent Application Publication
(10) Pub. No.: US 2026/0262358 A1
(43) Pub. Date: Sep. 3, 2026

(54) CHIP STRUCTURE AND DISPLAY PANEL

(71) Applicants: Beijing BOE Technology Development Co., Ltd., Beijing (CN); BOE Technology Group Co., Ltd., Beijing (CN)

(72) Inventors: Xiaohu LI, Beijing (CN); Yichi ZHANG, Beijing (CN); Wei LI, Beijing (CN); Mingxing WANG, Beijing (CN); Zhiqiang JIAO, Beijing (CN); Guangcai YUAN, Beijing (CN); Xue DONG, Beijing (CN)

(73) Assignees: Beijing BOE Technology Development Co., Ltd., Beijing (CN); BOE Technology Group Co., Ltd., Beijing (CN)

(21) Appl. No.: 18/995,880

(22) PCT Filed: Sep. 25, 2023
(86) PCT No.: PCT/CN2023/121237

§ 371 Date: Jan. 17, 2025

(51) Int. Cl. H10H 29/855; H10H 29/853

(52) U.S. Cl. CPC H10H 29/8552; H10H 29/853

(57) ABSTRACT

A chip structure includes a first substrate, a light emitting unit, and a color conversion unit. The light-shielding layer in the color conversion unit may include a body portion, and an extension portion surrounding the body portion. After light emitted from each sub-light-emitting functional layer in the light-emitting unit is emitted to the second semiconductor layer, and light is generated inside the second semiconductor layer by an optical waveguide phenomenon, the light emitted from the edge of the second semiconductor layer can be absorbed by the extension in the light-shielding layer.

This application is a US national stage of international application No. PCT/CN2023/121237, filed on Sep. 25, 2023, and the disclosure of which is incorporated herein by reference in its entirety.

### TECHNICAL FIELD

The present disclosure relates to the field of display technology, and in particular to a chip structure and a display panel.

### BACKGROUND

With the development of the display technology field, because of the light-emitting diode (mini Light-Emitting Diode, referred to as: LED) display panel has the advantages of pure chromaticity, wide dynamic range, high brightness, high clarity, low operating voltage, low power consumption, long service life, impact resistance, large viewing angle, and stable and reliable work, LED display panel will become the most advantageous new generation of LED display panel, and has been widely used.

### SUMMARY

Embodiments of the present disclosure provide a chip structure and a display panel. It can solve the problem of poor display effect of the LED display panel of the prior art, and the described technical solution is as follows.

On one hand, a chip structure is provided. The chip structure includes: a first substrate, a light-emitting unit and a color conversion unit, where the color conversion unit is disposed on a light-out side of the light-emitting unit and includes:
a light-shielding layer disposed on a side of the first substrate, where the light-shielding layer includes: a body portion and an extension portion surrounding the body portion, and the body portion has a plurality of light-through holes;
a defining dam layer disposed on a side of the light-shielding layer facing away from the first substrate, where the defining dam layer has a plurality of opening regions in a one-to-one correspondence with the plurality of light-through holes, an orthographic projection of each of the plurality of opening regions on the first substrate is overlapped with an orthographic projection of a corresponding light-through hole on the first substrate, and an orthographic projection of the body portion on the first substrate is overlapped with an orthographic projection of the defining dam layer on the first substrate, and the extension portion protrudes from an outer contour of the defining dam layer in a direction parallel to the first substrate;
a first encapsulation layer disposed between the light-shielding layer and the defining dam layer, where the first encapsulation layer covers the body portion and covers at least a portion of the extension portion;
an optical function layer disposed in each of the plurality of opening regions, where at least a portion of the optical function layer is configured to convert a color of light entering the optical function layer; and
a second encapsulation layer disposed on a side of the defining dam layer facing away from the first substrate, where the second encapsulation layer has a first contact region in contact with the first encapsulation layer and the first contact region is disposed around the defining dam layer.

Optionally, the first contact region has a shape of an annulus and the annulus has a width in a range of 0.5 μm to 60 μm; and
a shape enclosed by an outer contour of the first substrate is a rectangle, and a length and a width of the rectangle are less than or equal to 500 μm.

Optionally, a distance between an outer contour of the light-shielding layer and an outer contour of the first substrate is less than or equal to 20 μm in a direction parallel to the first substrate.

Optionally, an outer contour of the first substrate is flush with an outer contour of the light-shielding layer.

Optionally, the first substrate has a first side edge and a second side edge disposed opposite to each other, in the direction parallel to the first substrate, a distance between a part of an outer contour, which is adjacent to the first side edge, of the light-shielding layer and the first substrate is a first distance, a distance between another part of the outer contour, which is adjacent to the second side edge, of the light-shielding layer and the second side edge is a second distance, and a sum of the first distance and the second distance is greater than or equal to 5 μm.

Optionally, an outer contour of at least one of the first encapsulation layer and the second encapsulation layer is flush with an outer contour of the first substrate.

Optionally, a distance is present between an outer contour of at least one of the first encapsulation layer and the second encapsulation layer and an outer contour of the first substrate.

Optionally, an outer side surface of the first substrate is a fracture surface, and the fracture surface includes a first fracture portion, a second fracture portion, and a laser cutting portion disposed between the first fracture portion and the second fracture portion;
where the first fracture portion and the second fracture portion present traces of applied stress fracture, and the laser cutting portion presents ablation traces of laser cutting.

Optionally, the color conversion unit further includes a filtering layer disposed between the first substrate and the optical function layer, the filtering layer includes a plurality of filtering units in a one-to-one correspondence with the plurality of light-through holes, and an orthographic projection of each of the plurality of filtering units on the first substrate is overlapped with an orthographic projection of a corresponding light-through hole on the first substrate.

Optionally, an orthographic projection of the optical function layer on the first substrate and the orthographic projection of the defining dam layer on the first substrate are both disposed in an orthographic projection of the first encapsulation layer on the first substrate;
the light-filtering unit is disposed on a side of the first encapsulation layer facing away from the first substrate and a portion of the first encapsulation layer is disposed in each of the plurality of light-through holes; or
Alternatively, the light-filtering unit is disposed on a side of the first encapsulation layer facing the first substrate and at least a portion of the light-filtering layer is disposed in each of the plurality of light-through holes.

Optionally, the first encapsulation layer has a plurality of auxiliary holes in a one-to-one correspondence with the plurality of light-through holes, and an orthographic projection of each of the plurality of auxiliary holes on the first substrate is overlapped with an orthographic projection of each of the corresponding light-through holes on the first substrate;
at least a portion of the light-filtering unit is disposed in each of the plurality of auxiliary holes, and two opposite surfaces of the light-filtering unit are in contact with the first substrate and the optical function layer, respectively.

Optionally, the orthographic projection of each of the plurality of auxiliary holes on the first substrate is in the orthographic projection of each of the corresponding light-through holes on the first substrate, and a portion of the first encapsulation layer extends into the light-through holes and covers an inner wall of the light-through hole, such that the light-filtering unit is spaced apart from the light-shielding layer.

Optionally, the light-shielding layer has at least one annular through groove, and orthographic projections of the plurality of light-through holes on the first substrate are disposed in a region enclosed by an orthographic projection of the annular through groove on the first substrate; and
a portion of the first encapsulation layer is disposed in the annular through groove.

Optionally, the orthographic projection of the annular through groove on the first substrate is in the orthographic projection of the defining dam layer on the first substrate.

Optionally, the second encapsulation layer covers a surface of the defining dam layer facing away from the first substrate, and a surface of the optical function layer facing away from the first substrate and covers an outer side of the defining dam layer; and the light-emitting unit is disposed on a side of the second encapsulation layer facing away from the first substrate; and
the orthographic projection of the defining dam layer on the first substrate and the orthographic projection of the optical function layer on the first substrate are both disposed in an orthographic projection of the second encapsulation layer on the first substrate.

Optionally, materials of the first encapsulation layer and the second encapsulation layer are both inorganic materials.

Optionally, the chip structure further includes a connection layer disposed on a side of the second encapsulation layer facing away from the first substrate, where the light-emitting unit is disposed on a side of the connection layer facing away from the first substrate, and the light-emitting unit is fixed to the side of the second encapsulation layer facing away from the first substrate through the connection layer.

Optionally, the light-emitting unit includes: a plurality of sub-light-emitting function layers in a one-to-one correspondence with the plurality of opening regions, and an orthographic projection of each of the plurality of sub-light-emitting function layers on the first substrate is overlapped with an orthographic projection of a corresponding opening region on the first substrate.

Optionally, the plurality of sub-light-emitting function layers include a first sub-light-emitting function layer, a second sub-light-emitting function layer, and a third sub-light-emitting function layer, the plurality of sub-light-emitting function layers emit a first light in an operating state, and the first light includes at least one of blue light and ultraviolet light;
the plurality of opening regions includes a first opening region, a second opening region and a third opening region, where the first opening region is disposed corresponding to the first sub-light-emitting function layer, the second opening region is disposed corresponding to the second sub-light-emitting function layer, and the third opening region is disposed corresponding to the third sub-light-emitting function layer; and
the optical function layer includes a first color conversion section for converting the first light into red light, a second color conversion section for converting the first light into green light, and a third color conversion section for converting the first light into blue light or maintaining blue light; where the first color conversion section is disposed in the first opening region, the second color conversion section is disposed in the second opening region, and the third color conversion section is disposed in the third opening region.

Optionally, each of the plurality of sub-light-emitting function layers includes: a first electrode, a first semiconductor layer and a light-emitting layer stacked in a direction perpendicular to and facing the first substrate;
the light-emitting unit further includes a second semiconductor layer and a common electrode layer, and the second semiconductor layer is disposed on a light-out side of each of the plurality of sub-light-emitting function layers;
the second semiconductor layer includes: connection portions and auxiliary portions arranged in the direction parallel to the first substrate, where the connection portions are connected to the sub-light-emitting function layers, the auxiliary portions make the connection portions connect to each other, the connection portion and the auxiliary portion are integrated, and the common electrode layer is connected to the auxiliary portions.

Optionally, a material of the first semiconductor layer includes P-type doped gallium nitride, and the light-emitting layer is a multi-quantum well layer; and
the second semiconductor layer includes: a first sub-layer and a second sub-layer stacked along a direction perpendicular and facing the first substrate, where the first sub-layer is disposed between the second sub-layer and the light-emitting layer, a material of the first sub-layer is N-type doped gallium nitride, and the second sub-layer is a gallium nitride buffer layer.

Optionally, each of the plurality of sub-light-emitting function layers further includes: a current spreading layer disposed between the first electrode and the first semiconductor layer.

On the other hand, a display panel is provided, including a driving backplane, and a plurality of chip structures disposed in an array on a side of the driving backplane, where the chip structures are the chip structures as described above.

Beneficial effects brought by the technical solutions provided by the embodiments of the present disclosure include at least.

A chip structure includes a first substrate, a light-emitting unit, and a color conversion unit. A light-shielding layer in the color conversion unit may include a body portion, and an extension portion surrounding the body portion. After the light emitted from each of the sub-light-emitting function layers in the light-emitting unit is emitted to the second semiconductor layer, and the light generates an optical waveguide phenomenon inside the second semiconductor layer, the light emitted from the edge of the second semiconductor layer can be absorbed by the extension portion in the light-shielding layer, thereby reducing the probability of light leakage in the chip structure. As a result, the display panel integrated with the chip structure has a better display effect. As the first encapsulation layer is also provided between the light-shielding layer and the defining dam layer, and the first encapsulation layer can cover the body portion in the light-shielding layer, and the orthographic projection of the body portion in the light-shielding layer on the first substrate is overlapped with the orthographic projection of the defining dam layer on the first substrate. Therefore, after water and oxygen in the external environment intrudes into the light-shielding layer, water and oxygen inside the light-shielding layer can be isolated by the first encapsulation layer, such that water and oxygen do not intrude into the defining dam layer any more, thereby ensuring that water and oxygen intruding into the light-shielding layer do not erode the optical function layer, further improving the reliability of the optical function layer 303 and thus improving the stability of the chip structure.

### BRIEF DISCRIPTION OF DRAWINGS

For clearer descriptions of the technical solutions in the embodiments of the present disclosure, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a top view of a chip structure provided by some embodiments of the present disclosure;

FIG. 2 is a schematic structure diagram of a film layer of the chip structure at A-A′ illustrated in FIG. 1;

FIG. 3 is an effect diagram of an optical waveguide phenomenon generated inside a second semiconductor layer provided by some embodiments of the present disclosure;

FIG. 4 is a schematic structure diagram of another film layer of the chip structure at A-A′ illustrated in FIG. 1;

FIG. 5 is a schematic structure diagram of a film layer of another chip structure provided in the present disclosure;

FIG. 6 is a schematic structure diagram of a film layer of yet another chip structure provided by the present disclosure;

FIG. 7 is a schematic structure diagram of a first large plate provided by some embodiments of the present disclosure;

FIG. 8 is a schematic structure diagram of a first initial wafer provided by some embodiments of the present disclosure;

FIG. 9 is a schematic structure diagram of a second initial wafer provided by some embodiments of the present disclosure;

FIG. 10 is a schematic structure diagram of a second large plate provided by some embodiments of the present disclosure;

FIG. 11 is a schematic structure diagram of a motherboard wafer provided by some embodiments of the present disclosure;

FIG. 12 is a partially enlarged view of the motherboard wafer at B illustrated in FIG. 11;

FIG. 13 is another partially enlarged view of the motherboard wafer at B illustrated in FIG. 12;

FIG. 14 is a top view of another chip structure provided by some embodiments of the present disclosure;

FIG. 15 is a schematic diagram of an outer side surface of a first substrate provided by some embodiments of the present disclosure;

FIG. 16 is a top view of yet another chip structure provided by some embodiments of the present disclosure;

FIG. 17 is a schematic structure diagram of a film layer of the chip structure at C-C′ illustrated in FIG. 16;

FIG. 18 is a schematic structure diagram of a film layer of the chip structure at D-D′ illustrated in FIG. 16;

FIG. 19 is a schematic structure diagram of a film layer of a chip structure provided in another embodiment of the present disclosure;

FIG. 20 is a schematic structure diagram of a film layer of another chip structure provided in another embodiment of the present disclosure;

FIG. 21 is a schematic structure diagram of a film layer of yet another chip structure provided by another embodiment of the present disclosure;

FIG. 22 is a top view of a chip structure provided by yet another embodiment of the present disclosure;

FIG. 23 is a schematic structure diagram of a film layer of the chip structure at E-E′ illustrated in FIG. 22;

FIG. 24 is a schematic structure diagram of another film layer of the chip structure at E-E′ illustrated in FIG. 22;

FIG. 25 is a schematic structure diagram of yet another film layer of the chip structure at E-E′ illustrated in FIG. 22;

FIG. 26 is a top view of a light-emitting unit disposed on a connection layer provided by some embodiments of the present disclosure;

FIG. 27 is a schematic structure diagram of a film layer of the light-emitting unit at F-F′ illustrated in FIG. 26;

FIG. 28 is a top view of another light-emitting unit disposed on a connection layer provided by some embodiments of the present disclosure; and

FIG. 29 is a schematic structure diagram of a film layer of the light-emitting unit at G-G′ illustrated in FIG. 28.

### DETAILED DESCRIPTION

For clearer descriptions of the objectives, technical solutions, and advantages of the present disclosure, embodiments of the present disclosure are described in detail hereinafter with reference to the accompanying drawings.

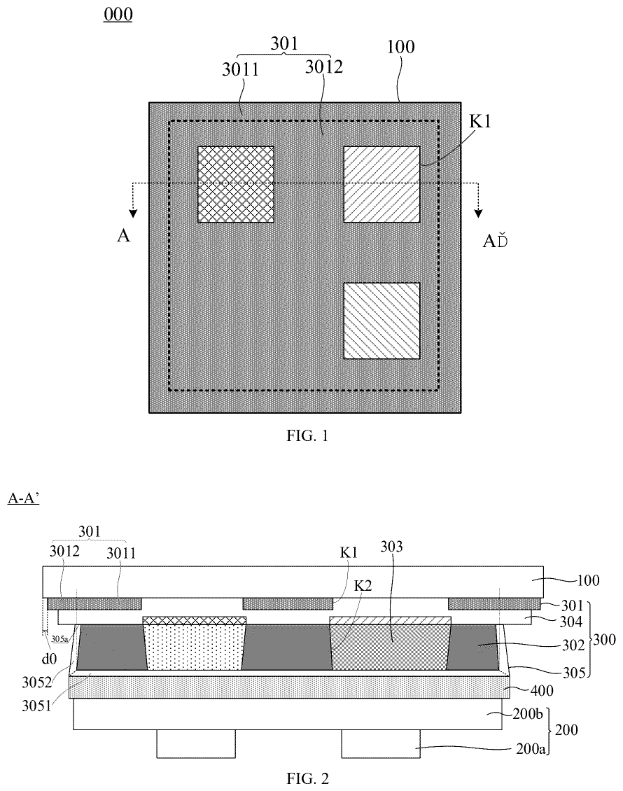

Referring to FIGS. 1 and 2, FIG. 1 is a top view of a chip structure provided by some embodiments of the present disclosure, and FIG. 2 is a schematic structure diagram of a film layer of the chip structure at A-A′ illustrated in FIG. 1. A chip structure 000 may include a first substrate 100, a light-emitting unit 200, and a color conversion unit 300. The color conversion unit 300 in the chip structure 000 may be disposed on a light-out side of the light-emitting unit 200. In one possible implementation, the color conversion unit 300 in the chip structure 000 may be disposed on a side of the first substrate 100, and the light-emitting unit 200 in the chip structure 000 may be disposed on a side of the color conversion unit 300 facing away from the first substrate 100. In this case, the light emitted from the light-emitting unit 200 may be emitted to the color conversion unit 300 and then emitted after passing through the color conversion unit 300 and the first substrate 100.

The color conversion unit 300 in the chip structure 000 may include a light-shielding layer 301, a defining dam layer 302, an optical function layer 303, and a second encapsulation layer 305.

The light-shielding layer 301 in the color conversion unit 300 may be disposed on a side of the first substrate 100. The light-shielding layer 301 may have a plurality of light-through holes K1.

The defining dam layer 302 in the color conversion unit 300 may be disposed on a side of the light-shielding layer 301 facing away from the first substrate 100. The defining dam layer 302 may have a plurality of opening regions K2 in a one-to-one correspondence with the plurality of light-through holes K1. Here, an orthographic projection of each of the plurality of opening regions K2 on the first substrate 100 may be overlapped with an orthographic projection of a corresponding light-through hole K1 on the first substrate 100.

The optical function layer 303 in the color conversion unit 300 may be disposed in each of the opening regions K2 of the defining dam layer 302, and at least a portion of the optical function layer 303 is configured to convert the color of the light that enters the optical function layer 303. Here, the light emitted from the light-emitting unit 200 in the chip structure 000 may be emitted to the optical function layer 303, and then is emitted through the light-through holes K1 of the light-shielding layer 301 after the optical function layer 303 converts the color of the light.

The second encapsulation layer 305 in the color conversion unit 300 may be disposed on a side of the defining dam layer 302 facing away from the first substrate 100. The second encapsulation layer 305 may encapsulate the defining dam layer 302 and the optical function layer 303 to prevent water and oxygen in the external environment from eroding the optical function layer 303 after passing through the defining dam layer 302, thereby ensuring that the optical function layer 303 is able to stably convert the colors of the light so that the optical function layer 303 is more reliable.

In some embodiments of the present disclosure, the light-emitting unit 200 in the chip structure 000 may include a plurality of sub-light-emitting function layers 200a. The plurality of sub-light-emitting function layers 200a in the light-emitting unit 200 may be in a one-to-one correspondence with the plurality of opening regions K2 in the defining dam layer 302. A light-out side of each of the plurality of sub-light-emitting function layers 200a may face a corresponding opening region K2, and an orthographic projection of each of the plurality of sub-light-emitting function layers 200a on the first substrate 100 may be overlapped with an orthographic projection of the corresponding opening region K2 on the first substrate 100. In one possible embodiment, an orthographic projection of each of the plurality of sub-light-emitting function layers 200a on the first substrate 100 may be disposed within an orthographic projection of the corresponding opening region K2 on the first substrate 100.

In this case, the light emitted from the sub-light-emitting function layers 200a in the light-emitting unit 200 can all be emitted to the optical function layer 303 in the corresponding opening regions K2 in the defining dam layer 302. It is to be noted that each sub-light-emitting function layer 200a in the light-emitting unit 200 can emit light of the same color, and the types of the optical function layer 303 filling in the different opening regions K2 are different, such that the light emitted from the sub-light-emitting function layers 200a can be converted into other light of different colors by the different types of optical function layers 303 after the light passes through the different opening regions K2.

It is also noted that the light-emitting unit 200 may further include a second semiconductor layer 200b disposed on light-out sides of the plurality of sub-light-emitting function layers 200a. As the light-out side of each of the sub-light-emitting function layers 200a in the light-emitting unit 200 faces the first substrate, each of the sub-light-emitting function layers 200a in the light-emitting unit 200 is disposed on a side of the same second semiconductor layer 200b facing away from the first substrate 100. That is, the second semiconductor layer 200b is closer to the first substrate 100 than the sub-light-emitting function layers 200a. In this way, in the light-emitting process of the sub-light-emitting function layers 200a, the light emitted from the sub-light-emitting function layers 200a passes through the second semiconductor layer 200b before the light is emitted to the color conversion unit 300.

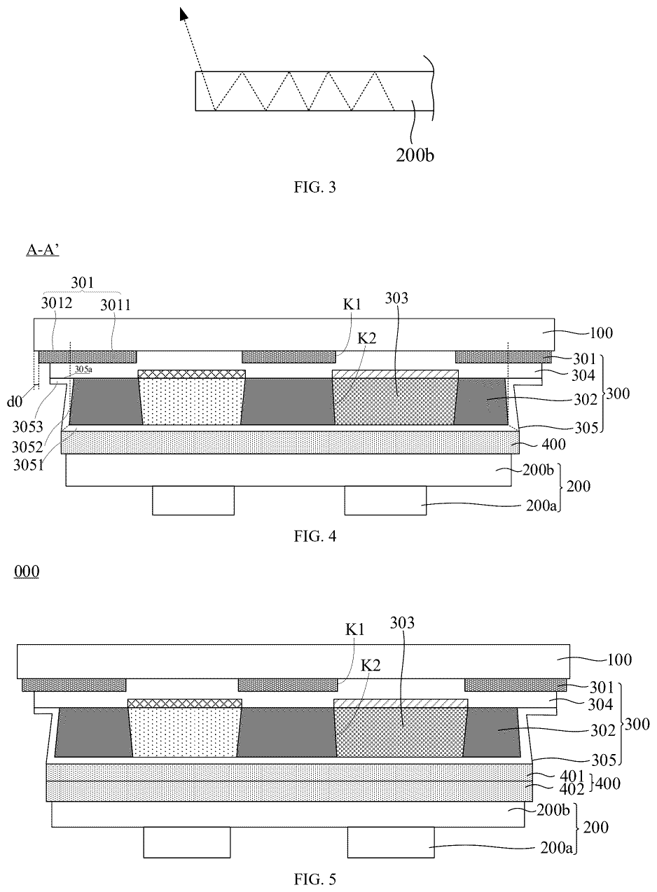

However, a portion of the light emitted to an inside of the second semiconductor layer 200b is prone to generating an optical waveguide phenomenon in the second semiconductor layer 200b. For example, referring to FIG. 3, FIG. 3 is an effect diagram of an optical waveguide phenomenon generated inside a second semiconductor layer provided by some embodiments of the present disclosure. A portion of the light emitted to the second semiconductor layer 200b can be fully reflected back and forth many times between two planes disposed opposite to each other in the second semiconductor layer 200b, transversely transmitted, and finally emitted from an edge of the second semiconductor layer 200b. After the optical waveguide phenomenon is generated inside the second semiconductor layer 200b, the light emitted from the edge of the second semiconductor layer 200b may not be absorbed by the light-shielding layer 301, which can easily lead to light leakage in the chip structure 000.

To this end, in the embodiments of the present disclosure, the light-shielding layer 301 in the color conversion unit 300 needs to be extended towards the outer contour of the first substrate 100, such that the extended light-shielding layer 301 can absorb light emitted from the edge of the second semiconductor layer 200b, thereby reducing the probability of light leakage in the chip structure 000.

Exemplarily, as indicated in FIG. 2, the light-shielding layer 301 may include a body portion 3011, and an extension portion 3012 surrounding the body portion 3011. The body portion 3011 in the light-shielding layer 301 may have a plurality of light-through holes K1, and an orthographic projection of the body portion 3011 on the first substrate 100 may be overlapped with an orthographic projection of a defining dam layer 302 in the color conversion unit 300 on the first substrate 100. The extension portion 3012 in the light-shielding layer 301 protrudes from an outer contour of the defining dam layer 302 in a direction parallel to the first substrate 100.

It is to be noted that an outer contour of a particular structure in the embodiments of the present disclosure refers to an outer boundary of an orthographic projection of the structure on a plane where the first substrate 100 is disposed. For example, the outer contour of the defining layer 302 refers to: an outer boundary of an orthographic projection of the defining dam layer 302 on a plane where the first substrate 100 is disposed. It is also noted that the outer boundary of the orthographic projection of the structure on the plane where the first substrate 100 is disposed can be typically disposed around a closed region, and thus the outer contour of the structure can also be disposed around a closed region. Here, in the case that the extension portion 3012 in the light-shielding layer 301 protrudes from the outer contour of the defining dam layer 302 in a direction parallel to the first substrate 100, the orthographic projection of the defining dam layer 302 on the first substrate 100 can be disposed in a region enclosed by an outer contour of the light-shielding layer 301 and a certain distance is present between the outer contour of the light-shielding layer 301 and the outer contour of the defining dam layer 302 in the direction parallel to the first substrate 100.

In one possible embodiment, the orthographic projection of the defining dam layer 302 on the first substrate 100 may be disposed within the orthographic projection of the body portion 3011 in the light-shielding layer 301 on the first substrate 100, and the orthographic projection of the extension portion 3012 in the light-shielding layer 301 on the first substrate 100 is not coincided with the orthographic projection of the defining dam layer 302 on the first substrate 100. That is, a boundary between the orthographic projection of the body portion 3011 in the light-shielding layer 301 on the first substrate 100, and the orthographic projection of the extension portion 3012 in the light-shielding layer 301 on the first substrate 100 is the outer contour of the orthographic projection of the defining dam layer 302 on the first substrate 100.

In this case, after the light emitted from each of the sub-light-emitting function layers 200a in the light-emitting unit 200 is emitted to the second semiconductor layer 200b and the light generates the optical waveguide phenomenon inside the second semiconductor layer 200b, and the light emitted from the edge of the second semiconductor layer 200b can be absorbed by the extension portion 3012 in the light-shielding layer 301, thereby reducing the probability of light leakage in the chip structure 000. As a result, the display panel in which the chip structure 000 is integrated has a better display effect.

Furthermore, after the light-shielding layer 301 is extended toward an edge of the first substrate 100, the second encapsulation layer 305 in the color conversion unit 300 can no longer encapsulate the light-shielding layer 301, such that water and oxygen in an external environment may intrude into the optical function layer 303 through the light-shielding layer 301 and the defining dam layer 302, thereby causing the failure of the optical functional layer 303. Therefore, a first encapsulation layer 304 needs to be disposed between the light-shielding layer 301 and the defining dam layer 302 in the color conversion unit 300. The first encapsulation layer 304 may cover the body portion 3011 in the light-shielding layer 301 and cover at least a portion of the extension portion 3012 in the light-shielding layer 301.

As the first encapsulation layer 304 is provided between the light-shielding layer 301 and the defining dam layer 302, and the first encapsulation layer 304 can cover the body portion 3011 in the light-shielding layer 301, and the orthographic projection of the body portion 3011 in the light-shielding layer 301 on the first substrate 100 is overlapped with the orthographic projection of the defining dam layer 302 on the first substrate 100. Therefore, after intruding into the light-shielding layer 301, water and oxygen inside the light-shielding layer 301 can be isolated by the first encapsulation layer 304, such that water and oxygen do not intrude into the defining dam layer 302 anymore, thereby ensuring that water and oxygen intruding into the light-shielding layer 301 do not erode the optical function layer 303, and further improving the reliability of the optical function layer 303.

In the present disclosure, the second encapsulation layer 305 in the color conversion unit 300 may be in contact with the first encapsulation layer 304, such that the second encapsulation layer 305 may have a first contact region 305a in contact with the first encapsulation layer 304. The first contact region 305a may be disposed around the defining dam layer 302.

Exemplarily, the second encapsulation layer 305 may cover a side of the defining dam layer 302 and of the optical function layer 303 facing away from the first substrate 100, and may cover an outer side surface of the defining dam layer 302. Both the orthographic projection of the defining dam layer 302 on the first substrate 100 and an orthographic projection of the optical function layer 303 on the first substrate 100 may be disposed in an orthographic projection of the second encapsulation layer 305 on the substrate 100. Here, a portion of the second encapsulation layer 305, which is disposed on an outer side surface of the defining dam layer 303, may be in contact with the first encapsulation layer 304 at a side, which faces the first substrate 100, of the portion of the second encapsulation layer 305. In this way, the sealing of the defining dam layer 302 and the optical function layer 303 through the cooperation of the first encapsulation layer 304 and the second encapsulation layer 305 can be achieved, such that the optical function layer 303 is not subjected to erosion by water and oxygen in the external environment.

In summary, the embodiments of the present disclosure provide a chip structure, including a first substrate, a light-emitting unit and a color conversion unit. The light-shielding layer in the color conversion unit may include a body portion, and an extension portion surrounding the body portion. After the light emitted from each of the sub-light-emitting function layers in the light-emitting unit is emitted to a second semiconductor layer and the light generates an optical waveguide phenomenon inside the second semiconductor layer, the light emitted from the edge of the second semiconductor layer can be absorbed by the extension portion in the light-shielding layer, thereby reducing the probability of light leakage in the chip structure. As a result, the display panel integrated with the chip structure has a better display effect. As the first encapsulation layer is also provided between the light-shielding layer and the defining dam layer, the first encapsulation layer can cover the body portion in the light-shielding layer, and the orthographic projection of the body portion in the light-shielding layer on the first substrate is overlapped with the orthographic projection of the defining dam layer on the first substrate, after intruding into the light-shielding layer, water and oxygen inside the light-shielding layer can be isolated by the first encapsulation layer, such that water and oxygen do not intrude into the defining dam layer any more, thereby ensuring that water and oxygen intruding into the light-shielding layer do not erode the optical function layer, further improving the reliability of the optical function layer and thus improving the stability of the chip structure.

Optionally, as indicated in FIG. 2, a material of both the first encapsulation layer 304 and the second encapsulation layer 305 in the color conversion unit 300 may be an inorganic insulating material. Exemplarily, the inorganic insulating material may include one or more of an oxide of silicon, a nitride of silicon, and a nitrogen oxide of silicon. The first encapsulation layer 304 and the second encapsulation layer 305 may both have a thickness ranging from 0.5 μm to 5 μm. In this way, both the defining dam layer 302 and the optical function layer 303 can be isolated from the external environment through the cooperation of the first encapsulation layer 304 and the second encapsulation layer 305, such that water and oxygen in the external environment do not erode the optical function layer 303.

In the embodiments of the present disclosure, a material of the first substrate 100 is glass. For example, the first substrate 100 may transmit a visible light band.

In the embodiments of the present disclosure, an extension surface of the first substrate 100 (i.e., an upper or a lower surface of the first substrate 100) may be a plane.

In the embodiments of the present disclosure, a shape of a region enclosed by the outer contour of the first substrate 100 in the chip structure 000 is a rectangle, and both a length and a width of the rectangle are less than or equal to 500 μm. It should be noted that the length and the width of the rectangle may also be the same, i.e., the shape of the region enclosed by the outer contour of the first substrate 100 may also be a square. In this case, an overall size of the chip structure 000 is smaller, and after a plurality of the chip structures 000 are fixed to a driving backplane, it can ensure that an obtained display panel has a higher resolution. Exemplarily, both the length and the width of the rectangle may range from 200 μm to 400 μm. In this case, the preparation process of the chip structure 000 can be simplified on the premise that the overall size of the chip structure 000 is smaller.

Optionally, within the color conversion unit 300 in the chip structure 000, a shape of the first contact region 305a where the second encapsulation layer 305 is in contact with the first encapsulation layer 304 may be an annulus and a width of the annulus is in the range of 0.5 μm to 60 μm.

In one possible implementation, a minimum width of the first contact region 305a where the second encapsulation layer 305 is in contact with the first encapsulation layer 304 is the thickness of the second encapsulation layer 305 itself. In this case, as indicated in FIG. 2, the second encapsulation layer 305 in the color conversion unit 300 may include a first encapsulation portion 3051 and a second encapsulation portion 3052 which are connected. The first encapsulation portion 3051 may cover a side of the defining dam layer 302 and of the optical function layer 303 facing away from the first substrate 100. That is, both the orthographic projection of the defining dam layer 302 on the first substrate 100 and the orthographic projection of the optical function layer 303 on the first substrate 100 are within an orthographic projection of the first encapsulation portion 3051 on the first substrate 100. The second encapsulation portion 3052 may cover an outer side surface of the defining dam layer 302. Here, a side of the second encapsulation portion 3052 in the second encapsulation layer 305 facing the first substrate 100 may be in contact with the first encapsulation layer 304, i.e., a region where the second encapsulation portion 3052 is in contact with the first encapsulation layer 304 is the first contact region 305a. Here, a width of the first contact region 305a is the thickness of the second encapsulation portion 3052, and the thickness of the second encapsulation portion 3052 is the thickness of the second encapsulation layer 305. Therefore, the minimum width of the first contact region 305a where the second encapsulation layer 305 is in contact with the first encapsulation layer 304 may also be in a range of 0.5 μm to 5 μm.

In another possible implementation, as indicated in FIG. 4, FIG. 4 is a schematic diagram of another film layer structure of the chip structure at A-A′ illustrated in FIG. 1. The second encapsulation layer 305 may further include a third encapsulation portion 3053. The third encapsulation portion 3053 may be connected to a side of the second encapsulation portion 3052 facing away from the first encapsulation portion 3051, and may be disposed on a side of the first encapsulation layer 304 facing away from the first substrate 100. In this way, the first contact region 305a where the second encapsulation layer 305 is in contact with the first encapsulation layer 304 may not only include the side of the second encapsulation portion 3052 facing the first substrate 100, but may also include the third encapsulation portion 3053. In this case, the side of the third encapsulation portion 3053 facing away from the second encapsulation portion is an outer contour of the second encapsulation layer 305. In the case that the outer contour of the second encapsulation layer 305 is flush with the outer contour of the first encapsulation layer 304, and the outer contours of both the first encapsulation layer 304 and the second encapsulation layer 305 are flush with the outer contour of the first substrate 100, the width of the first contact region 305a where the second encapsulation layer 305 is in contact with the first encapsulation layer 304 is the maximum width, which is equal to a distance between the outer contour of the defining dam layer 302 and an outer contour of the first substrate 100. Also, as a distance between the outer contour of the defining dam layer 302 and the outer contour of the first substrate 100 needs to be less than or equal to 60 μm to ensure that a distance between two pixels of the subsequently obtained display panel is closer. Therefore, the maximum width range of the first contact region 305a where the second encapsulation layer 305 is in contact with the first encapsulation layer 304 also needs to be less than or equal to 60 μm.

As can be seen, the width of the first contact region 305a where the second encapsulation layer 305 is in contact with the first encapsulation layer 304 is in a range of 0.5 μm to 60 μm.

It is noted that the first encapsulation layer 304 and the second encapsulation layer 305 in the color conversion unit 300 may both be patterned, or both may not be patterned, or one may be patterned and the other may not be patterned, in the process of preparation.

For example, in the case that the first encapsulation layer 304 and the second encapsulation layer 305 are both patterned and the purpose of the patterning is to enable that the first encapsulation layer 304 and the second encapsulation layer 305 can be formed by using the same composition process while forming a second cut channel pattern in the subsequent embodiments. That is, after both the first encapsulation layer 304 and the second encapsulation layer 305 are prepared, the first encapsulation layer 304 and the second encapsulation layer 305 are then patterned simultaneously. In this case, the outer contour of the second encapsulation layer 305 is flush with the outer contour of the first encapsulation layer 304.

As another example, in the case that neither the first encapsulation layer 304 nor the second encapsulation layer 305 is patterned, the first encapsulation layer 304 and the second encapsulation layer 305 need to be cut at the same time in a process of forming the single chip structure 000 by the cutting process in the subsequent embodiments. In this case, the outer contour of the second encapsulation layer 305 is also flush with the outer contour of the first encapsulation layer 304.

Optionally, the chip structure 000 may further include a connection layer 400 disposed on the side of the second encapsulation layer 305 facing away from the first substrate 100. Here, the light-emitting unit 200 in the chip structure 000 may be disposed on a side of the connection layer 400 facing away from the first substrate 100, and the light-emitting unit 200 may be fixed on the side of the second encapsulation layer 305 facing away from the first substrate 100 by the connection layer 400.

It should be noted that the color conversion unit 300 and the light-emitting unit 200 in the chip structure 000 in the present disclosure are prepared independently, and then the two are fixed together by the connection layer 400 to obtain the chip structure 000.

Optionally, first, a plurality of color conversion units 300 can be formed on a second substrate that is connected together and has a large area, and a connection layer 400 can be formed on a side of the plurality of color conversion units 300 facing away from the second substrate. After that, a plurality of light-emitting units 200 can be formed on a third substrate (typically a sapphire substrate or a silicon-based substrate), and then the third substrate is removed and the light-emitting units 200 are fixed to the side of the corresponding color conversion units 300 facing away from the second substrate through the connection layer 400. Finally, the second substrate can be cut by a cutting process, and the plurality of chip structures 000 can be obtained.

Optionally, the connection layer 400 in the chip structure 000 may include any one of an indium zinc oxide connection layer, a metal connection layer, and an adhesive glue layer. For different types of connection layer 400, the principle by which the connection layer 400 fixes the color conversion unit 300 and the light-emitting unit 200 together is different. Therefore, the embodiments of the present disclosure are schematically illustrated with the following three possible cases.

In a first possible case, in the case that the connection layer 400 includes the adhesive glue layer, the connection layer 400 is a single-layer structure by which the color conversion unit 300 and the light-emitting unit 200 can be bonded together. Exemplarily, the material of the adhesive glue layer 133 is an organic adhesive material of the epoxy resin type. Moreover, the adhesive layer is transparent, such that even if the adhesive layer covers each sub-light-emitting function layer 200a in the light-emitting unit 200, it can be ensured that each sub-light-emitting function layer 200a is able to pass through the adhesive layer and then be emitted to the corresponding opening region K2.

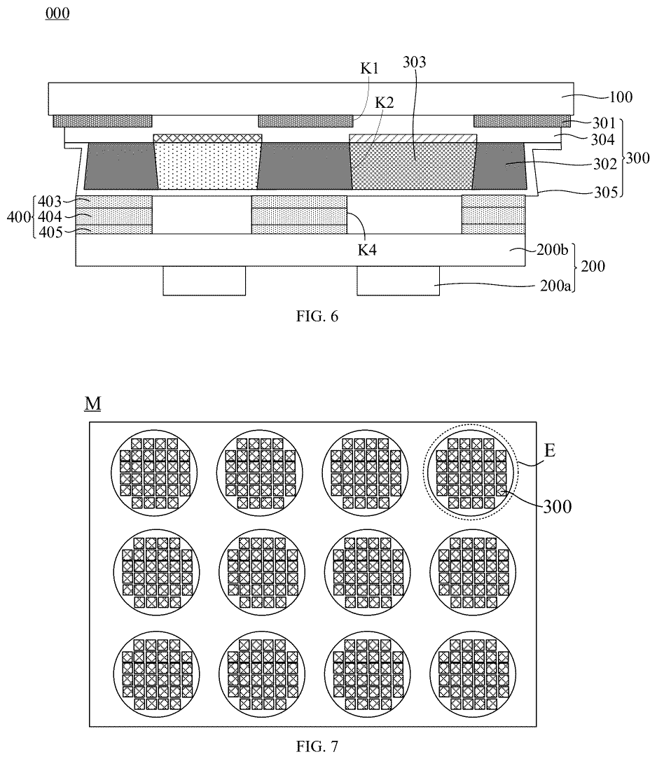

In a second possible case, referring to FIG. 5, FIG. 5 is a schematic diagram of a film layer structure of another chip structure provided in the present disclosure. In the case that the connection layer 400 includes an indium-zinc oxide connection layer, the connection layer 400 may include a first indium-zinc oxide layer 401 and a second indium-zinc oxide layer 402 that are stacked. Here, the first indium-zinc oxide layer 401 and the second indium-zinc oxide layer 402 may be connected by molecular bonding cooperation.

The first indium-zinc oxide layer 401 may be fixed on a side of the color conversion unit 300 facing away from the first substrate 100, and the second indium-zinc oxide layer 402 may be fixed on the light-out side of the light-emitting unit 200. In this way, the color conversion unit 300 and the light-emitting unit 200 being fixed to each other can be achieved through molecular bonding cooperation between the first indium zinc oxide layer 401 and the second indium zinc oxide layer 402.

It should be noted that the first indium-zinc oxide layer 401 and the second indium-zinc oxide layer 402 are transparent conductive layers. Therefore, even though the first indium-zinc oxide layer 401 and the second indium-zinc oxide layer 402 both cover each sub-light-emitting function layer 200a in the light-emitting unit 200, it can be ensured that each light emitted from sub-light-emitting function layer 200a can pass through the second indium-zinc oxide layer 402 and the first indium-zinc oxide layer 401, and then be emitted to the corresponding opening region K2.

In a third possible case, referring to FIG. 6, FIG. 6 is a schematic diagram of a film layer structure of yet another chip structure provided in the present disclosure. In the case that the connection layer 400 includes a metal connection layer, the connection layer 400 may include a first sub-metal layer 403, a second sub-metal layer 404, and a third sub-metal layer 405 that are stacked. The second sub-metal layer 404 may be disposed between the first sub-metal layer 403 and the third sub-metal layer 405, and may serve as a eutectic alloy layer for connecting the first sub-metal layer 403 and the third sub-metal layer 405.

The first sub-metal layer 403 may be fixed on the side of the color conversion unit 300 facing away from the first substrate 100, and the third sub-metal layer 405 may be fixed on the light-out side of the light-emitting unit 200. In this way, the first sub-metal layer 403 and the third sub-metal layer 405 may be connected as a whole by the eutectic alloy layer (also the second sub-metal layer 404) so as to fix the color conversion unit 300 and the light-emitting unit 200.

It should be noted that the first sub-metal layer 403, the second sub-metal layer 404, and the third sub-metal layer 405 are all electrically conductive layers with a light reflection property. Therefore, a plurality of avoidance holes K4 corresponding to the plurality of sub-light-emitting function layers 200a in the light-emitting unit 200 need to be provided in the connection layer 400 to ensure that light emitted from each sub-light-emitting function layer 200a is able to pass through a corresponding avoidance hole K4 and then emitted to the corresponding opening region K2.

Optionally, the light-emitting unit 200 in the chip structure 000 may include a plurality of light-emitting chips, and each of the light-emitting chips may have one sub-light-emitting function layer 200a. The light-emitting chip is an LED chip. It should be noted that the LED chip may be an ordinary-sized LED chip, a mini light-emitting diode (mini-LED) chip, or a micro light-emitting diode (Micro-LED) chip, which is not limited in the embodiments of the present disclosure.

The following embodiments schematically illustrate the preparation process of the chip structure 000 by taking the connection layer 400 including the first indium-zinc oxide layer 401 and the second indium-zinc oxide layer 402 as an example. Here, the preparation process of the chip structure 000 may include the following structural steps.

In S101, the first indium-zinc oxide layer 401 is formed on the color conversion unit 300.

In the embodiments of the present disclosure, in the process of preparing the color conversion units 300 as indicated in FIG. 7 which is a schematic structure diagram of a first large plate provided in some embodiments of the present disclosure, a first large plate M including a plurality of the color conversion units 300 that are arranged in an array may be formed first synchronously, and then a first indium-zinc-oxide layer 401 may be formed on each of the color conversion units 300 in the first large plate M. For example, the first indium-zinc oxide layer 401 may be formed on each of the color conversion units 300 by a photolithography process, and then the first large plate M is cut to obtain a plurality of first initial wafers E. Each of the first initial wafers E may include a second substrate, color conversion units 300 disposed on the second substrate and the first indium-zinc oxide layer 401 disposed on the side of each of the color conversion units 300 facing away from the second substrate 401.

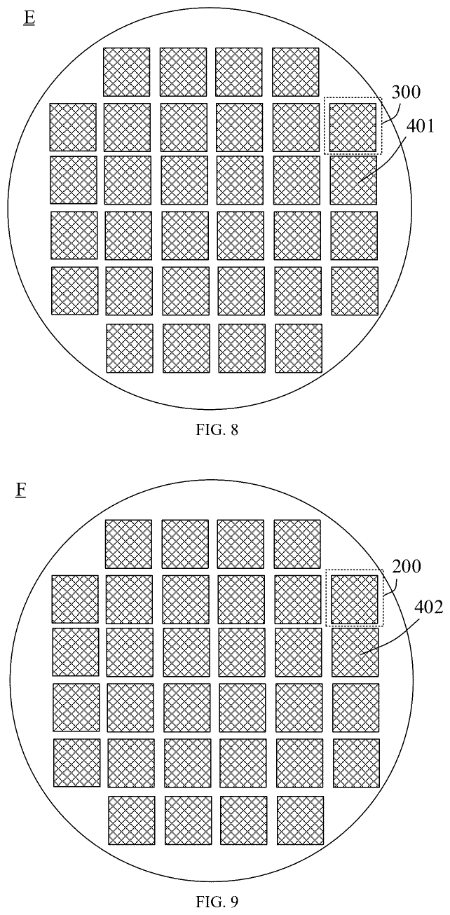

Exemplarily, as indicated in FIGS. 7 and 8, FIG. 8 is a schematic structure diagram of a first initial wafer provided by some embodiments of the present disclosure. A shape of the first initial wafer E may be circular, and a plurality of first initial wafers E may be cut out in the first large plate M by anisotropically cutting the first large plate M.

In S102, a second indium-zinc oxide layer 402 is formed on the light-out side of the light-emitting unit 200.

In the embodiments of the present disclosure, the light-emitting unit 200 is formed on a third substrate, and before the third substrate is removed, a temporary substrate needs to be formed on the side of the light-emitting unit 200 facing away from the third substrate. The third substrate can be stripped from the light-emitting unit 200 after the temporary substrate is formed. It should be noted that the light-emitting unit 200 with the temporary substrate may be referred to as an initial light-emitting unit. That is, the light-emitting unit 200 can be obtained by removing the temporary substrate from the initial light-emitting unit.

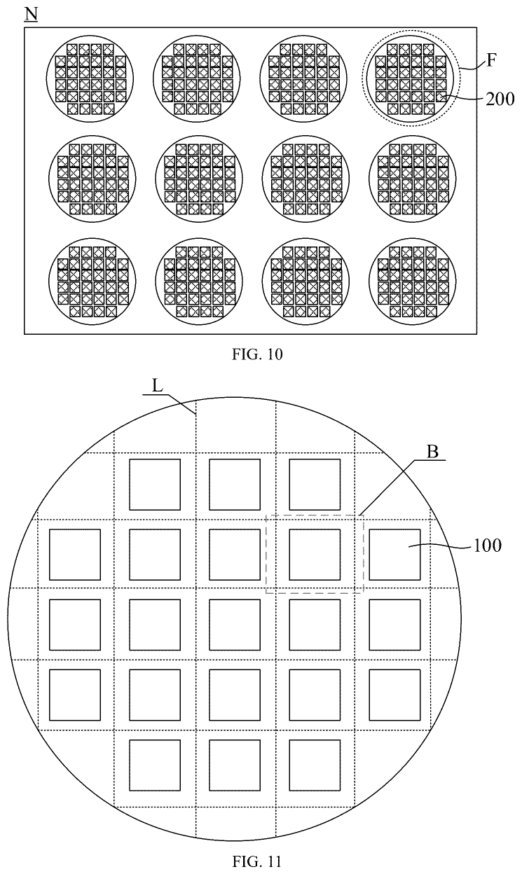

In one example, as indicated in FIG. 9, FIG. 9 is a schematic structure diagram of a second initial wafer provided by some embodiments of the present disclosure. A plurality of light-emitting units 200 arranged in arrays may be formed on a circular third substrate in the process of preparing initial light-emitting units, and then temporary substrates are formed on a side of the plurality of light-emitting units 200 facing away from the third substrate to obtain the plurality of initial light-emitting units. Here, the temporary substrates in the initial light-emitting units may be connected as a whole, i.e., the temporary substrate may be a whole substrate with a large area, and the shape of the temporary substrate may also be circular. Finally, a second indium-zinc oxide layer 402 may be formed on a side of each of the initial light-emitting units facing away from the temporary substrate, and a second initial wafer including a plurality of initial light-emitting units may be obtained.

In another example, in the process of preparing the initial light-emitting units, as indicated in FIG. 10 which is a schematic structure diagram of a second large plate provided by some embodiments of the present disclosure, a second large plate N including a plurality of initial light-emitting units that are arranged in an array may be formed first synchronously, and then a second indium-zinc oxide layer 402 may be formed on each initial light-emitting unit in the second large plate N. Here, the second indium-zinc oxide layer 402 may be formed on a side of the light-emitting unit 200 in each initial light-emitting unit facing away from the temporary substrate. For example, the first indium-zinc oxide layer 401 may be formed on each color conversion unit 300 by a photolithographic process, and then a plurality of second initial wafers F may be obtained by cutting the second large plate N. Each of the second initial wafers F may include a plurality of initial light-emitting units and a second indium zinc oxide layer 402 disposed on each initial light-emitting unit.

Exemplarily, a shape of the second initial wafer F may be circular, and a plurality of second initial wafers F may be cut out in the second large plate N by anisotropic cutting of the second large plate N. The shape of each of the second initial wafers F may refer to the second initial wafers F illustrated in FIG. 9.

It is to be noted that the temporary substrate within each of the initial light emitting units in the second initial wafer F may be connected as one. That is, the temporary substrate may be a substrate having the same shape as the second initial wafer F and having a larger area, and the individual light emitting units 200 in the second initial wafer F may all be disposed on this temporary substrate.

In S103, the first indium-zinc oxide layer 401 and the second indium-zinc oxide layer 402 are bonded.

In the embodiments of the present disclosure, bonding of the first initial wafer E and the second initial wafer F can be achieved by bonding of the first indium-zinc oxide layer 401 and the second indium-zinc oxide layer 402. The plurality of color conversion units 300 in the first initial wafer E and the plurality of initial light-emitting units in the second initial wafer F are bonded in a one-to-one correspondence.

It is noted that the step of bonding the first indium-zinc oxide layer 401 and the second indium-zinc oxide layer 402 includes the following sub-steps.

In sub-step S103a, a surface of the first indium-zinc oxide layer 401 on a side away from the temporary substrate is treated with an oxygen plasma to activate the surface of the first indium-zinc oxide layer 401.

In sub-step S103b, a surface of the second indium-zinc oxide layer 402 on a side away from the initial second substrate is treated with an oxygen plasma to activate the surface of the second indium-zinc oxide layer 402.

In sub-step S103c, the first indium-zinc oxide layer 401 and the second indium-zinc oxide layer 402 are pressed together under certain temperature conditions to form the connection layer 400.

The first indium-zinc oxide layer 401 and the second indium-zinc oxide layer 402 can be bonded together by the above sub-step 103a to sub-step 103c.

In S104, the temporary substrate is removed to obtain a motherboard wafer.

In the embodiments of the present disclosure, a second substrate, a plurality of color conversion units 300 disposed on the second substrate, and a plurality of light-emitting units 200 disposed on the side of each color conversion unit 300 facing away from the second substrate can be obtained by removing a temporary substrate from the second initial wafer F. Herein, the second substrate, as well as the plurality of color conversion units 300 and the plurality of light-emitting units 200 disposed on the second substrate may be referred to as the motherboard wafer.

In S105, the motherboard wafer is cut to obtain the plurality of chip structures 000.

In the embodiments of the present disclosure, the single chip structure 000 is obtained after the motherboard wafer is cut. Here, referring to FIG. 11, FIG. 11 is a schematic structure diagram of a motherboard wafer provided in some embodiments of the present disclosure. The motherboard wafer may include a plurality of chip structures 000, and the plurality of chip structures 000 may be obtained after the motherboard wafer is cut in accordance with a cutting line L. Each of the plurality of chip structures 000 includes the first substrate 100, the light-emitting unit 200, and the color converting unit 300 in the above-described embodiments. Here, in the process of cutting the motherboard wafer, it is necessary to cut the second substrate in the motherboard wafer that is connected together and has a large area. After cutting the second substrate, the plurality of chip structures 000 can be obtained, and the first substrate 100 in each of the plurality of chip structures 000 is a portion of the second substrate in the motherboard wafer.

In the present disclosure, the defining dam layer 302 in the color conversion unit 300 needs to be encapsulated by the first encapsulation layer 304 and the second encapsulation layer 305. Therefore, before the motherboard wafer is cut, the defining dam layers 302 in each of the plurality of chip structures 000 are independently distributed. In this way, after the motherboard wafer is cut, all positions in the defining dam layers 302 in the obtained chip structures 000 can be encapsulated by the first encapsulation layer 304 and the second encapsulation layer 305. It is to be noted that before the motherboard wafer is cut, the first substrates 101 in the chip structures 000 are connected to each other. Here, a structure obtained after the first substrates 101 in the chip structures 000 are connected together is the second substrate, and each of the light-shielding layers 301, the first encapsulation layers 304, and the second encapsulation layers 305 in adjacent chip structures 000 may be connected together or may not. Preferably, remaining structures in the adjacent chip structures 000 are not connected to each other to ensure easy separation after cutting. Therefore, the embodiments of the present disclosure are described in the following three possible implementations.

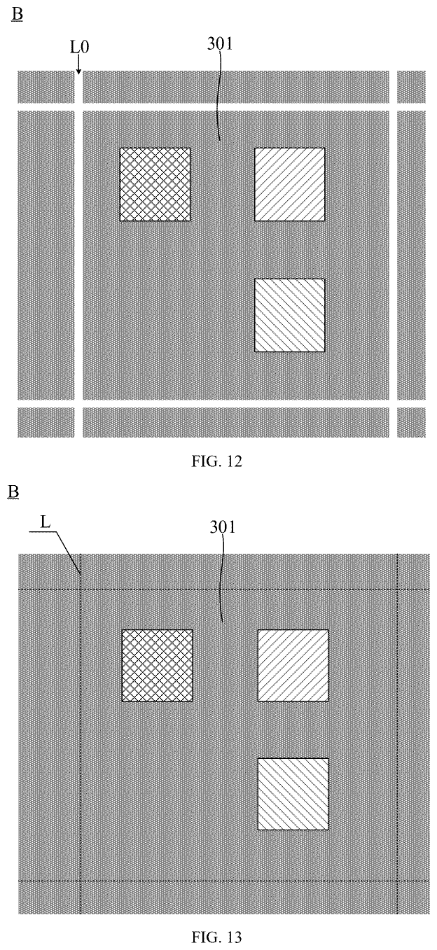

In a first possible implementation, only the first substrates 101 in the chip structures 000 are connected to each other before the motherboard wafer is cut, and the light-shielding layers 301, the first encapsulation layers 304 and the second encapsulation layers 305 in the chip structures 000 are not connected to each other. In this case, as indicated in FIG. 12, FIG. 12 is a partially enlarged view of the motherboard wafer at B as illustrated in FIG. 11. A first cut channel pattern L0 and a second cut channel pattern need to be formed in the preparation process of the first large plate M before the motherboard wafer is cut. Here, the first cut channel pattern L0 may be disposed between the light-shielding layers 301 within two adjacent chip structures 000, and the second cut channel pattern may be disposed between the first encapsulation layer 304 and the second encapsulation layer 305 within two adjacent chip structures 000. That is, before the motherboard wafer is cut, the light-shielding layers 301 in the chip structures 000 may be separated from each other by the first cut channel pattern LO, the first encapsulation layers 304 in the chip structures 000 may be separated from each other by the second cut channel pattern, and the second encapsulation layers 305 in the chip structures 000 may be also separated from each other by the second cut channel pattern.

The motherboard wafer is then cut in accordance with the first cut channel pattern L0 and the second cut channel. In this way, during the process of cutting the motherboard wafer, only the second substrate may be cut, such that within each chip structure 000 obtained after the motherboard wafer is cut, a certain distance may be present between the outer contour of the light-shielding layer 301 and the outer contour of the first substrate 100 in a direction parallel to the first substrate 100. For example, referring to FIG. 2, a distance do between the outer contour of the light-shielding layer 301 and the outer contour of the first substrate 100 in a direction parallel to the first substrate 100 may be less than or equal to 20 μm. In this way, it can be ensured that the light leakage emitted from an edge of the second semiconductor layer 200b can be absorbed by the extension portion 3012 in the light-shielding layer 301.

It is to be noted that when the first cut channel pattern L0 is formed between two light-shielding layers 301 within the adjacent chip structures 000 in the motherboard wafer, an operator can cut the second substrate in the motherboard wafer based on a position of the first cut channel pattern L0. In this way, the difficulty of cutting the second substrate in the motherboard wafer can be decreased. Moreover, it can also be ensured that the outer contour of the light-shielding layer 301 in each chip structure 000 after cutting is not burnt, such that the light-shielding layer 301 can provide a better light-shielding effect.

It is also noted that the second cut channel pattern is similar to the first cut channel pattern in the light-shielding layer 301. By providing the second cutting channel, it can be ensured that the first encapsulation layer 304 and the second encapsulation layer 305 are not cut during the process of cutting the motherboard wafer, thereby effectively avoiding the generation of microcracks inside the first encapsulation layer 304 and the second encapsulation layer 305 which extend to the interior of the chip structure 000 during the cutting of the first encapsulation layer 304 and the second encapsulation layer 305, thereby effectively improving the product stability of the chip structure 000.

In a second possible implementation, before the motherboard wafer is cut, the first substrates 101 in the chip structures 000 are connected to each other and the light-shielding layers 301 in the chip structures 000 are also connected to each other, but neither the first encapsulation layer 304 nor the second encapsulation layer 305 in the chip structures 000 are connected to each other. In this case, as indicated in FIG. 13, FIG. 13 is another partial enlarged view of the motherboard wafer at B as illustrated in FIG. 12, the first cut channel pattern LO may not be formed during the preparation of the first large plate M before the motherboard wafer is cut, but the second cut channel pattern may be formed. That is, before the motherboard wafer is cut, the first encapsulation layers 304 in the chip structures 000 may be separately from each other by the second cut channel pattern, and the second encapsulation layers 305 in the chip structures 000 may be separately from each other by the second cut channel pattern.

In this way, the second substrate in the motherboard wafer can be cut during the process of cutting the motherboard wafer. After the second substrate is cut to obtain the plurality of chip structures 000, the light-shielding layers connected together can be disconnected along the outer contours of the first substrates 100 in the chip structures 000. In this case, the outer contour of the light-shielding layer 301 is flush with the outer contour of the first substrate 100 within each of the chip structures 000 obtained after the motherboard wafer is cut. In this way, the light leakage emitted from an edge of the second semiconductor layer 200b can certainly be absorbed by the extension portion 3012 in the light-shielding layer 301.

In a third possible implementation, before the motherboard wafer is cut, the first substrates 101 in the chip structures 000 are connected to each other, and the light-shielding layers 301, the first encapsulation layers 304, and the second encapsulation layers 305 in the chip structures 000 are all connected to each other as well. In this case, the first cut channel pattern L0 and the second cut channel pattern may not be formed during the preparation of the first large plate M before the motherboard wafer is cut. Thus, neither the first encapsulation layer nor the second encapsulation layer needs to be patterned. Moreover, the second substrate in the motherboard wafer may be cut during the process of cutting the motherboard wafer. After the second substrate is cut to obtain a plurality of chip structures 000, the light-shielding layers, the first encapsulation layers, and the second encapsulation layers which are connected together may be disconnected along the outer contour of the first substrate 100 in each of the plurality of chip structures 000. In this case, in each of the plurality of chip structures 000 obtained after the motherboard wafer is cut, outer contours of the first substrate 100, the light-shielding layer 301, the first encapsulation layer 304, and the second encapsulation layer 305 are all flush. In this way, the light leakage emitted from an edge of the second semiconductor layer 200b can certainly be absorbed by the extension portion 3012 in the light-shielding layer 301.

It should be noted that as a shape enclosed by the outer contour of the light-shielding layer 301 and a shape enclosed by the first substrate 100 may both be rectangular. Therefore, a distance between each side edge of the light-shielding layer 301 and an adjacent side edge of the first substrate 100 needs to be less than or equal to 20 μm in the direction parallel to the first substrate 100.

In the present disclosure, a relationship between an outer contour of at least one of the first encapsulation layer 304 and the second encapsulation layer 305 in the color conversion unit 300 and the outer contour of the light-shielding layer 301 satisfies any one of the followings.

In a first case, an outer contour of at least one of the first encapsulation layer 304 and the second encapsulation layer 305 is flush with an outer contour of the light-shielding layer 301. Exemplarily, the outer contour of the first encapsulation layer 304 may be flush with the outer contour of the light-shielding layer 301, or, the outer contour of the second encapsulation layer 305 may be flush with the outer contour of the light-shielding layer 301, or, outer contours of the first encapsulation layer 304 and the second encapsulation layer 305 may be both flush with the outer contour of the light-shielding layer 301.

In a second case, a distance is present between an outer contour of at least one of the first encapsulation layer 304 and the second encapsulation layer 305, and an outer contour of the first substrate 100.

Exemplarily, the outer contour of the first encapsulation layer 304 is closer to the outer contour of the first substrate 100 than the outer contour of the light-shielding layer 301.

Exemplarily, the outer contour of the second encapsulation layer 305 is closer to the outer contour of the first substrate 100 than the outer contour of the light-shielding layer 301.

Exemplarily, the outer contours of both the first encapsulation layer 304 and the second encapsulation layer 305 are closer to the outer contour of the first substrate 100 than the outer contour of the light-shielding layer 301.

Exemplarily, the outer contour of the light-shielding layer 301 is closer to the outer contour of the first substrate 100 than the outer contour of the first encapsulation layer 304.

Exemplarily, the outer contour of the light-shielding layer 301 is closer to the outer contour of the first substrate 100 than the outer contour of the second encapsulation layer 305.

Exemplarily, the outer contour of the light-shielding layer 301 is closer to the outer contour of the first substrate 100 than both the outer contours of the first encapsulation layer 304 and the second encapsulation layer 305.

Exemplarily, the outer contour of the first encapsulation layer 304 is closer to the outer contour of the first substrate 100 than the outer contour of the second encapsulation layer 305.

Exemplarily, the outer contour of the second encapsulation layer 305 is closer to the outer contour of the first substrate 100 than the outer contour of the first encapsulation layer 304.

That a distance may be present between the outer contour of the first encapsulation layer 304 and the outer contour of the first substrate 100 is taken as an example and will be described.

The first substrate 100 may have a first side edge and a second side edge disposed opposite to each other. In the chip structure 000, in a direction parallel to the first substrate 100, a distance between a part of an outer contour, which is adjacent to the first side edge, of the first encapsulation layer 304 and the first side edge is a third distance, and a distance between another part of the outer contour, which is adjacent to the second side edge, of the first encapsulation layer 304 and the second side edge is a fourth distance.

The sum of the third distance and the fourth distance is substantially the same as a width of the second cut channel pattern illustrated in the above embodiments. As the width of the second cut channel pattern in the subsequent embodiments needs to be greater than or equal to 5 μm, the sum of the third distance and the fourth distance is also greater than or equal to 5 μm. Preferably, the sum of the third distance and the fourth distance is greater than or equal to 10 μm.

It is to be noted that, when the motherboard wafer is cut, whether the second cut channel pattern is formed in at least one of the first encapsulation layer 304 and the second encapsulation layer 305 in the motherboard wafer, and whether the first cut channel pattern is formed within the light-shielding layer 301 will ultimately determine the relationship between the outer contours of the first encapsulation layer 304 and the light-shielding layer 301.

Exemplarily, if the second cut channel pattern is not formed in at least one of the first encapsulation layer 304 and the second encapsulation layer 305 in the motherboard wafer and the first cut channel pattern is not formed in the light-shielding layer 301, in the chip structure 000 obtained after the motherboard wafer is cut, outer contours of the first encapsulation layer 304 and the light-shielding layer 301 are flush and are both flush with the outer contour of the first substrate 100.

If the second cut channel pattern is not formed in at least one of the first encapsulation layer 304 and the second encapsulation layer 305 in the motherboard wafer and the first cut channel pattern is formed in the light-shielding layer 301, in the chip structure 000 obtained after the motherboard wafer is cut, the outer contour of at least one of the first encapsulation layer 304 and the second encapsulation layer 305 is closer to the outer contour of the first substrate 100 than the light-shielding layer 301, and the outer contour of at least one of the first encapsulation layer 304 and the second encapsulation layer 305 is flush with the outer contour of the first substrate 100.

If the second cut channel pattern is formed in at least one of the first encapsulation layer 304 and the second encapsulation layer 305 in the motherboard wafer and the first cut channel pattern is formed in the light-shielding layer 301, the outer contour of at least one of the first encapsulation layer 304 and the second encapsulation layer 305 is closer to the outer contour of the first substrate 100 than the outer contour of the light-shielding layer 301 in the case that a width of the second cut channel pattern is smaller than that of the first cut channel pattern. In the case that the width of the second cut channel pattern is greater than that of the first cut channel pattern, the outer contour of the light-shielding layer 301 is closer to the outer contour of the first substrate 100 than the outer contour of at least one of the first encapsulation layer 304 and the second encapsulation layer 305. In the case that the width of the second cut channel pattern is equal to that of the first cut channel pattern, the outer contour of the light-shielding layer 301 is flush with the outer contour of at least one of the first encapsulation layer 304 and the second encapsulation layer 305.

It should be noted that in the case that the second cut channel is formed in both the first encapsulation layer 304 and the second encapsulation layer 305 and the first cut channel pattern is formed in the light-shielding layer 301, in order to simplify the cutting process, it is necessary to cut as far as possible along a centre line of the first cut channel pattern in the process of cutting the motherboard wafer. In the process, in order to ensure that the first encapsulation layer 304 and the second encapsulation layer 305 are not cut, the width of the second cut channel pattern can be larger than the width of the first cut channel pattern. In this way, in the process of cutting along the first cut channel pattern, the first encapsulation layer 304 and the second encapsulation layer 305 are certainly not cut, such that microcracks are not generated in both the first encapsulation layer 304 and the second encapsulation layer 305. Therefore, the accompanying drawings in the embodiments of the present disclosure are all illustrated with the outer contour of the light-shielding layer 301 being closer to the outer contour of the first substrate 100 than the outer contours of the first encapsulation layer 304 and the second encapsulation layer 305.

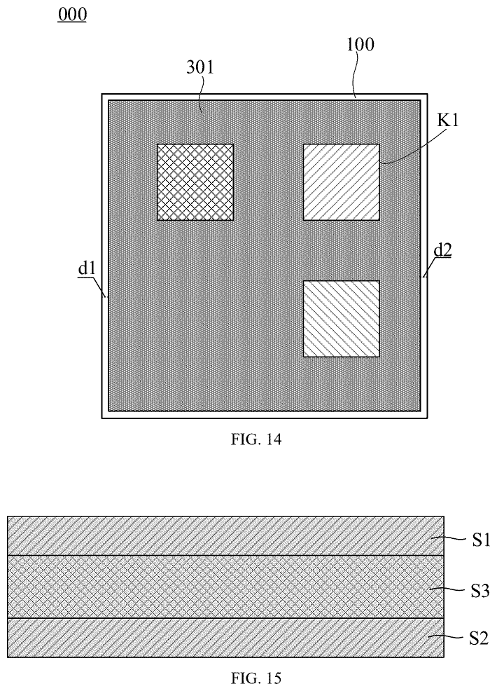

In this case, for the single chip structure 000 obtained after the second substrate in the motherboard wafer is cut, refer to FIG. 14. FIG. 14 is a top view of another chip structure provided in some embodiments of the present disclosure. The first substrate 100 may have a first side edge and a second side edge disposed opposite to each other. In the chip structure 000, in a direction parallel to the first substrate 100, a distance between a part of an outer contour, which is adjacent to the first side edge, of the light-shielding layer 301 and the first side edge is a first distance d1, and a distance between another part of the outer contour, which is adjacent to the second side edge, of the light-shielding layer 301 and the second side edge is a second distance d2. It is to be noted that FIG. 14 is illustrated as an example for schematic illustration in which the first side edge is a side edge on a left side of the chip structure 000 and the second side edge is a side edge on a right side of the chip structure 000.

The sum of the first distance d1 and the second distance d2 is substantially the same as a width of the first cut channel pattern L0 illustrated in FIG. 12. As the width of the first cut channel pattern L0 illustrated in FIG. 12 needs to be greater than or equal to 5 μm, the sum of the first distance d1 and the second distance d2 is also greater than or equal to 5 μm. Preferably, the sum of this first distance d1 and the second distance d2 is greater than or equal to 10 μm.

In the embodiments of the present disclosure, the second substrate in the motherboard wafer may be cut by means of laser stealth cutting. During the cutting process, the laser cutting beam can be focused to a middle position of the second substrate in a thickness direction of the second substrate, such that the middle position of the second substrate can be melted or vaporized. Then a tool can be used to apply a force to an upper surface and/or a lower surface of the second substrate, such that a portion of the second substrate that belongs to the first substrate 100 in the single chip structure 000 can be separated off. It is to be noted that as the laser cutting beam reaches the middle position of the second substrate, no extra debris (e.g., cutting sparks) is generated and sputtered onto the light-emitting unit 200 or the color conversion unit 300 in the cutting process, such that the reliability of the chip structure 000 obtained by a subsequent cutting is higher.

In this case, after the second substrate in the motherboard wafer is cut, an outer side surface of the first substrate 100 in the obtained chip structure 000 is a fracture surface. Here, referring to FIG. 15, FIG. 15 is a schematic diagram of an outer face of a first substrate provided by some embodiments of the present disclosure. The fracture surface may include a first fracture portion S1, a second fracture portion S2, and a laser cutting portion S3 disposed between the first fracture portion S1 and the second fracture portion S2. The first fracture portion S1 and the second fracture portion S2 may present traces of applied stress fracture, and the laser cutting portion S3 may present ablation traces of the laser cutting.

In the present disclosure, as the laser cutting beam is focused on the middle position of the second substrate during the process of cutting the second substrate, the middle position of the outer side surface of the first substrate 101 in the single chip structure 000 obtained after the second substrate is cut presents ablation traces of the laser cutting. Also, as in the process of cutting the second substrate, after the laser cutting beam melts or vaporises the middle position of the second substrate, it is necessary to apply a force to an upper surface and/or a lower surface of the second substrate by using a cutting knife to achieve the cutting of the second substrate. As a result, in the outer side surface of the first substrate 101 in the single chip structure 000 obtained after the second substrate is cut, stress fracture traces are presented on both sides of the ablation traces.

It is to be noted that for the first substrate 100 in the single chip structure 000 obtained by cutting, as the middle position of the outer side surface of the first substrate 100 presents the ablation traces of the laser cutting, the outer side surface of the first substrate 100 disposed on both sides of the middle position presents fracture traces. As a result, the outer side surface of the first substrate 100 is not a complete plane. In this way, the distance between the outer contour of the first substrate 100 and the outer contour of the other film layer (e.g., the light-shielding layer 301) is not a fixed value. Therefore, the present disclosure may refer to the distance between the outer contour of the first substrate 100 and the outer contour of the other film layer as: an average distance between the outer contour of the first substrate 100 and the outer contour of the other film layer.

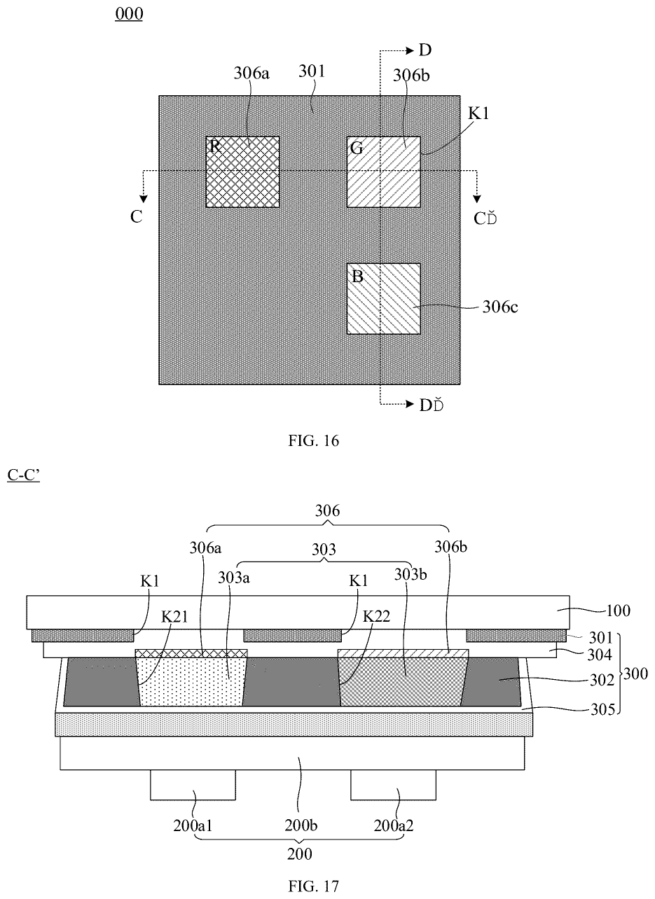

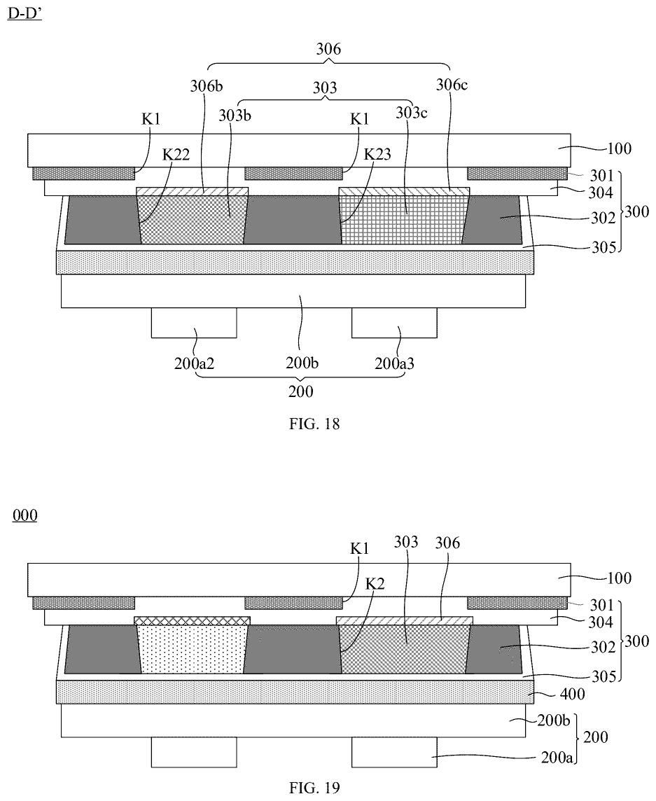

In the embodiments of the present disclosure, as illustrated in FIG. 16, FIG. 17 and FIG. 18, FIG. 16 is a top view of yet another chip structure provided by some embodiments of the present disclosure, FIG. 17 is a schematic diagram of a film layer structure of the chip structure at C-C′ illustrated in FIG. 16, and FIG. 18 is a schematic diagram of a film layer structure of the chip structure at D-D′ illustrated in FIG. 16. A plurality of sub-light-emitting function layers in the light-emitting unit 200 may include a first sub-light-emitting function layer 200a1, a second sub-light-emitting function layer 200a2, and a third sub-light-emitting function layer 200a3. The first sub-light-emitting function layer 200a1, the second sub-light-emitting function layer 200a2, and the third sub-light-emitting function layer 200a3 are all used to emit a first light in an operating state.

Accordingly, the plurality of opening regions in the defining dam layer 302 may include a first opening region K21, a second opening region K22, and a third opening region K23. The first opening region K21 may be disposed opposite to the first sub-light-emitting function layer 200a1, the second opening region K22 may be disposed opposite to the second sub-light-emitting function layer 200a2, and the third opening region K23 may be disposed opposite to the third sub-light-emitting function layer 200a3.

The optical function layer 303 in the color conversion unit 300 may include a first color conversion section 303a, a second color conversion section 303b and a third color conversion section 303c. The first color conversion section 303a may be disposed in the first opening region K21, the second color conversion section 303b may be disposed in the second opening region K22, and the third color conversion section 303c may be disposed in the third opening region K23.

In this case, the first light emitted from the first sub-light-emitting function layer 200a1 may be emitted to the first color conversion section 303a, and may be converted by the first color conversion section 303a to light of another color. The first light emitted from the second sub-light-emitting function layer 200a1 may be emitted to the second color conversion section 303b, and may be converted by the second color conversion section 303b to light of another color. The first light emitted from the third sub-light-emitting function layer 200a3 may be emitted to the third color conversion section 303c, and may transmit through the third color conversion section 303c or may be converted by the third color conversion section 303c.

Exemplarily, the chip structure 000 may have a red sub-pixel R, a green sub-pixel G, and a blue sub-pixel B. The first light emitted from the first sub-light-emitting function layer 200a1, the second sub-light-emitting function layer 200a2, and the third sub-light-emitting function layer 200a3 in the light-emitting unit 200 includes at least one of: blue light and ultraviolet light.

The first color conversion section 303a is configured to convert the first light to red light. Exemplarily, the first color conversion section 303a includes red quantum dots for converting the first light to the red light. Preferably, the first color conversion section 303a also includes scattering particles for scattering the light. After the first light emitted from the first sub-light-emitting function layer 200a1 is emitted to the first color conversion section 303a distributed in the first opening region K21, the first light is able to be converted to the red light by the red quantum dots, and the first light and the red light are able to be scattered by the scattering particles, thereby ensuring that more first light is able to be converted to the red light by the red quantum dots, an emergent angle of the converted red light is larger, and then a viewing angle of the display panel integrated with the chip structure 000 is larger. Therefore, the red sub-pixel R in the chip structure 000 may include the first sub-light-emitting function layer 200a1 and the first color conversion section 303a.

The second color conversion section 303b is configured to convert the first light to green light. Exemplarily, the second color conversion section 303b includes green quantum dots for converting the first light to the green light. Preferably, the second color conversion section 303b also includes scattering particles for scattering the light. After the first light emitted from the second sub-light-emitting function layer 200a2 is emitted to the second color conversion section 303b distributed in the second opening region K22, the first light can be converted to the green light by the green quantum dots, and the first light and the green light are able to be scattered by the scattering particles, thereby ensuring that more first light is able to be converted to the green light by the green quantum dots, an emergent angle of the converted green light is larger, and then a viewing angle of the display panel integrated with the chip structure 000 is larger. Therefore, the green sub-pixel G in the chip structure 000 may include the second sub-light-emitting function layer 200a2 and the second color conversion section 303b.

The third color conversion section 303c is configured to convert the first light to the blue light or to maintain emission of the blue light. For example, in the case that the first light includes only the blue light, the third color conversion section 303c may be a transparent section or the third color conversion section 303c may include blue quantum dots. The transparent section is configured to directly transmit the first light, and the blue quantum dots may be configured to convert the first light to the blue light with a wavelength different from the first light. Preferably, the third color conversion section 303c also includes scattering particles for scattering the light. After the first light emitted from the third sub-light-emitting function layer 200a3 is emitted to the third color conversion section 303c distributed in the third opening region K23, the first light is able to be scattered by the scattering particles, thereby ensuring that an emergent angle of the converted the blue light is larger, and then a viewing angle of the display panel integrated with the chip structure 000 is larger. For example, in the case that the first light includes the ultraviolet light, the third color conversion section 303c includes the blue quantum dots for converting the first light to the blue light, or the third color conversion section 303c has both scattering particles for scattering the light and the blue quantum dots for converting the ultraviolet light to the blue light distributed in the third color conversion section 303c. After the first light emitted from the second sub-light-emitting function layer 200a2 is emitted to the third color conversion section 303c distributed in the third opening region K23, the ultraviolet light in the first light is able to be converted to the blue light by the blue quantum dots, and the first light and the blue light can be scattered by the scattering particles, thereby ensuring that more ultraviolet light is able to be converted to the blue light by the blue quantum dots, an emergent angle of the converted blue light is larger, and then a viewing angle of the display panel integrated with the chip structure 000 is larger. Therefore, the blue sub-pixel B in the chip structure 000 may include the third sub-light-emitting function layer 200a3 and the third color conversion section 303c.

In the embodiments of the present disclosure, the color conversion unit 300 in the chip structure 000 may further include a filtering layer 306 disposed between the first substrate 100 and the optical function layer 200, where the filtering layer 306 may include a plurality of filtering units in a one-to-one correspondence with the plurality of light-through holes K1. An orthographic projection of each of the filtering unit on the first substrate 100 may be overlapped with an orthographic projection of the corresponding light-through hole on the first substrate 100.

Exemplarily, the plurality of filtering units in the filtering layer 306 may include a first filtering unit 306a, a second filtering unit 306b, and a third filtering unit 306c. The first filtering unit 306a may be disposed corresponding to the first color conversion section 303a, the second filtering unit 306b may be disposed corresponding to the second color conversion section 303b, and the third filtering unit 306c may be disposed corresponding to the third color conversion section 303c. Therefore, the red sub-pixel R in the chip structure 000 may further include the first filtering unit 306a; the green sub-pixel G in the chip structure 000 may further include the second filtering unit 306b; and the blue sub-pixel B in the chip structure 000 may further include the third filtering unit 306c.

For example, the first light emitted from the first sub-light-emitting function layer 200a1, the second sub-light-emitting function layer 200a2, and the third sub-light-emitting function layer 200a3 in the light-emitting unit 200 is all the blue light. The first filtering unit 306a can be a red color block, which transmits the red light and absorbs the light of other colors. In this way, the light emitted from the first color conversion section 303a can be emitted after passing through the first filtering unit 306a, and the first filtering unit 306a is capable of filtering out light of other colors other than red light, thereby ensuring that the red sub-pixels R in the chip structure 000 are capable of filtering out the blue light components. It is to be noted that in other possible implementations, the first filtering unit 306a may also be: a film layer for transmitting the red light and reflecting the blue light. In this way, after the light emitted from the first color conversion section 303a are emitted to the first filtering unit 306a, the red light in the light may be transmitted through the first filtering unit 306a and then emitted. The blue light in the light may be reflected by the first filtering unit 306a back to the first color conversion section 303a, such that the red quantum dots in the first color conversion section 303a can again excite the blue light into the red light, and then the excitation efficiency of the red quantum dots can be further improved.

For example, the first light emitted from the first sub-light-emitting function layer 200a1, the second sub-light-emitting function layer 200a2, and the third sub-light-emitting function layer 200a3 in the light-emitting unit 200 is all the blue light. The second filtering unit 306b can be a green color block which can transmit green light and absorb light of other colors. In this way, the light emitted from the second color conversion section 303b can be emitted after passing through the second filtering unit 306b, and the second filtering unit 306b is capable of filtering out light of colors other than the green light, thereby ensuring that the green sub-pixels G in the chip structure 000 are capable of filtering out the blue light component. It is to be noted that in other possible implementations, the second filtering unit 306b may also be: a film layer for transmitting the green light and reflecting the blue light. In this way, after the light emitted from the second color conversion section 303b are emitted to the second filtering unit 306b, the green light in the light may be transmitted through the second filtering unit 306b and then emitted. The blue light in the light may be reflected by the second filtering unit 306b back to the second color conversion section 303b, such that the green quantum dots in the second color conversion section 303b can again excite the blue light into the green light, and then the excitation efficiency of the green quantum dots can be further improved.

It should be noted that the film layer structures of the first filtering unit 306a and the second filtering unit 306b may be the same, and may be prepared by the same process, for example, both the first filtering unit 306a and the second filtering unit 306b are a film layer that transmits the red light and the green light and reflects the blue light.

For example, the first light emitted from the first sub-light-emitting function layer 200a1, the second sub-light-emitting function layer 200a2, and the third sub-light-emitting function layer 200a3 in the light-emitting unit 200 is all the blue light. The third filtering unit 306c can be a blue color block, which transmits the blue light and absorbs light of other colors. In this way, the light emitted from the third color conversion section 303c can be transmitted through the third filtering unit 306c and then emitted, and the third filtering unit 306c is capable of filtering out other colors of light other than the blue light, thereby ensuring that the blue sub-pixels B in the chip structure 000 can emit relatively pure blue light.

For example, the first light emitted from the first sub-light-emitting function layer 200a1, the second sub-light-emitting function layer 200a2, and the third sub-light-emitting function layer 200a3 in the light-emitting unit 200 is all the blue light. The third filtering unit 306c may be a transparent block, which transmits the blue light.

It is to be noted that as an orthographic projection of each filtering unit in the filtering layer 306 on the first substrate 100 is overlapped with the orthographic projection of the corresponding light-through hole K1 in the light-shielding layer 301 on the first substrate 100, a portion in the light-shielding layer 301 will be distributed between two adjacent filtering units in the filtering layer 306 in a direction parallel to the first substrate 100. In this way, the light emitted from the side surface of a certain filtering unit in the filtering layer 306 can be absorbed by the light-shielding layer 301, such that it can be ensured that the light emitted from each sub-pixel is not emitted to the adjacent sub-pixel, and the probability of color crosstalk occurring in the chip structure 000 can be effectively reduced.

In the embodiments of the present disclosure, the structures of the first encapsulation layer 304 in the color conversion unit 300 are various, and the embodiments of the present disclosure are schematically illustrated by taking the following two implementations as examples.

In a first implementation, as indicated in FIG. 19, FIG. 19 is a schematic structure diagram of a film layer structure of a chip structure provided in another embodiment of the present disclosure. A first encapsulation layer 304 in a color conversion unit 300 is a film layer structure disposed as a whole on the first substrate 100, i.e., the first encapsulation layer 304 disposed on the first substrate 100 is not patterned. In this case, orthographic projections of the optical function layer 303 and the defining dam layer 302 in the color conversion unit 300 on the first substrate 100 may both be disposed in an orthographic projection of the first encapsulation layer 304 on the substrate 100. In this way, the first encapsulation layer 304 can cover a side of the optical function layer 303 facing the first substrate 100 and cover a side of the defining dam layer 302 facing the first substrate 100, such that after intruding into a light-shielding layer 301, the water and the oxygen can be isolated by the first encapsulation layer 304, and thus the water and oxygen which has intruded into the light-shielding layer 301 will not intrude into the defining dam layer 302 from the side of the defining dam layer 302 facing the first substrate 100, and will not intrude into the optical function layer 303 from the side of the optical function layer 303 facing the first substrate 100.

The first encapsulation layer 304 in the color conversion unit 300 is disposed between the light-shielding layer 301 and the defining dam layer 302. The positional relationship between the first encapsulation layer 304 in the color conversion unit 300 and the light-filtering layer 306 are various, and the embodiments of the present disclosure are schematically illustrated by taking the following two cases as examples.

In a first case, as indicated in FIG. 19, the filtering layer 306 in the color conversion unit 300 may be disposed on a side of the first encapsulation layer 304 facing away from the first substrate 100, and a portion of the first encapsulation layer 304 may be disposed in a light-through hole K1 in the light-shielding layer 301. A side of the filtering layer 306 facing away from the first substrate 100 may be in direct contact with the side of the optical function layer 303 facing the first substrate 100.

Optionally, the orthographic projection of each filtering unit in the filtering layer 306 on the first substrate 100 can cover the orthographic projection of the corresponding opening region K2 in the defining dam layer 302 on the first substrate 100. In this way, the light emitted from the optical function layer 303 distributed in the opening region K2 of the defining dam layer 302 can all be emitted to the corresponding light-filtering unit in the filtering layer 306, thereby ensuring that the filtering unit filters the light more effectively, and making the color of the light subsequent emitted from the corresponding light-through hole K1 in the light-shielding layer 301 purer.

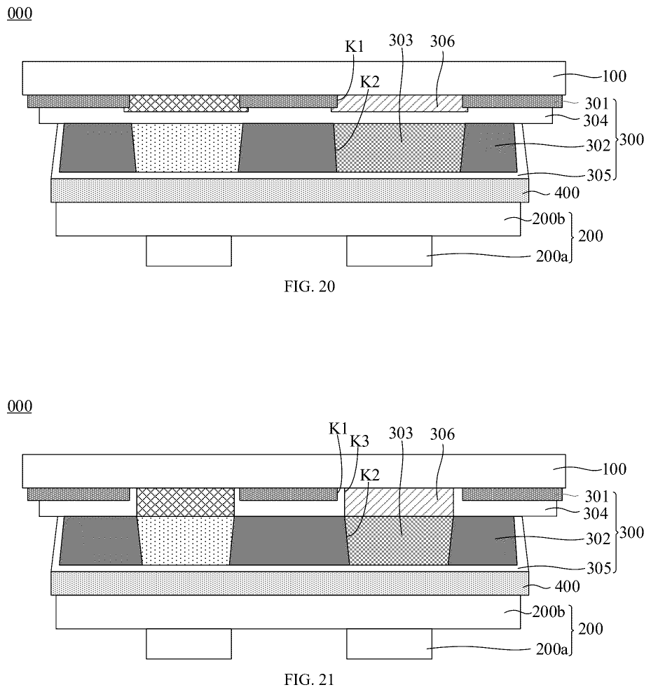

In the second case, as indicated in FIG. 20, FIG. 20 is a schematic structure diagram of a film layer structure of another chip structure provided in another embodiment of the present disclosure. A filtering layer 306 in a color conversion unit 300 may be disposed on a side of a first encapsulation layer 304 facing a first substrate 100, and at least a portion of each filtering unit in the filtering layer 306 may be disposed in the corresponding light-through hole K1 in a light-shielding layer 301. The side of the first encapsulation layer 304 in the color conversion unit 300 facing the first substrate 100 may be in direct contact with a side of the light-shielding layer 301 facing away from the first substrate 100, and may be in direct contact with a side of the filtering layer 306 facing away from the first substrate 100. The side of the first encapsulation layer 304 in the color conversion unit 300 facing away from the first substrate 100 may be in direct contact with a side of a defining dam layer 302 facing the first substrate 100, and may be in direct contact with a side of an optical function layer 303 facing the first substrate 100.

Optionally, the orthographic projection of each filtering unit in the filtering layer 306 on the first substrate 100 may cover the orthographic projection of the corresponding light-through hole K1 in the light-shielding layer 301 on the first substrate 100. In the filtering layer 306, a portion of each filtering unit may be distributed in the corresponding light-through hole K1 in the light-shielding layer 301, and another portion may be distributed outside the corresponding light-through hole K1. In this way, the light emitted from the optical function layer 303 distributed in the opening region K2 of the defining dam layer 302 can all be filtered by the corresponding filtering unit in the light-filtering layer 306 after being emitted to the corresponding through-hole K1 in the light-shielding layer 301, thereby ensuring that the filtering effect of the light-filtering unit on the light is better, and making the color of the light emitted from the corresponding through-hole K1 in the light-shielding layer 301 purer.

In a second implementation, as indicated in FIG. 21, FIG. 21 is a schematic diagram of a film layer structure of yet another chip structure provided in another embodiment of the present disclosure. A first encapsulation layer 304 in a color conversion unit 300 is a film layer structure that is patterned on a first substrate 100, i.e., the first encapsulation layer 304 disposed on the first substrate 100 needs to be patterned. In this case, the first encapsulation layer 304 may have a plurality of auxiliary holes K3 in a one-to-one correspondence with a plurality of light-through holes K1 in the light-shielding layer 301, and an orthographic projection of each auxiliary hole K3 in the first encapsulation layer 304 on the first substrate 100 may be overlapped with an orthographic projection of a corresponding light-through hole K1 in the light-shielding layer 301 on the first substrate 100.

At least a portion of each filtering units in the filtering layer 306 may be disposed in a corresponding auxiliary hole K3 in the first encapsulation layer 304 and may be disposed in a corresponding light-through hole K1 in the light-shielding layer 301. Two sides of each filtering unit in the filtering layer 306 that are disposed opposite to each other may be in contact with the first substrate 100 and the optical function layer 303. Exemplarily, a portion of each filtering unit in the filtering layer 306 disposed in the corresponding light-through hole K1 facing the side of the first substrate 100 may be in direct contact with the first substrate 100. The side of each filtering unit in the filtering layer 306 facing away from the substrate 100 may be in direct contact with the side of the optical function layer 304 in the corresponding hole K2 in the defining dam layer 302 facing the side of the first substrate 100.

In this case, as the plurality of auxiliary holes K3 are disposed in the first encapsulation layer 304, and two sides of each filtering unit in the filtering layer 306 that are disposed opposite to each other are in direct contact with the first substrate 100 and the optical function layer 303, the light emitted from the optical function layer 303 distributed in the opening region K2 of the defining dam layer 302 can be emitted to the corresponding filtering unit in the filtering layer 306, and the light emitted from the filtering unit can be emitted to be emitted after passing through the first substrate 100. Therefore, the light emitted from the optical function layer 303 does not pass through the first encapsulation layer 304, such that the light emitted to the first encapsulation layer 304 can be avoided from generating an optical waveguide phenomenon in the first encapsulation layer 304, thereby ensuring that the light emitted from the optical function layer 303 distributed in a certain opening region K2 is not transmitted to the sub-pixels where the adjacent opening region K2 is disposed, and further reducing the probability of color crosstalk occurring in the chip structure 000.

Optionally, the orthographic projection of each filtering unit in the filtering layer 306 on the first substrate 100 may cover the orthographic projection of the corresponding opening region K2 in the defining dam layer 302 on the first substrate 100, thereby ensuring that the light emitted from the optical function layer 303 has a purer color of light after passing through the first substrate 100.

In an optional implementation, in the case that the first encapsulation layer 304 in the color conversion unit 300 is patterned to obtain the film layer structure on the first substrate 100, the orthographic projection of each auxiliary hole K3 in the first encapsulation layer 304 on the first substrate 100 may be disposed in the orthographic projection of the corresponding through-light hole K1 in the light-shielding layer 301 on the first substrate 100. A portion of the first encapsulation layer 304 may extend into the through-light hole K1 of the light-shielding layer 301, and the portion of the first encapsulation layer 304 extending into the through-light hole K1 may cover the inner wall of the through-light hole K1. In this way, it can be ensured that the filtering unit and the light-shielding layer 301 are spaced apart. Water and oxygen intruding into the light-shielding layer 301 can be isolated in a direction parallel to the first substrate 100 by the portion of the first encapsulation layer 304 extending into the light-through hole K1. In this manner, even if two opposite sides of each filtering unit in the filtering layer 306 are in direct contact with the first substrate 100 and the optical function layer 303, it can be ensured that water and oxygen intruding into the light-shielding layer 301 do not erode the optical function layer 303 through the filtering layer 306.

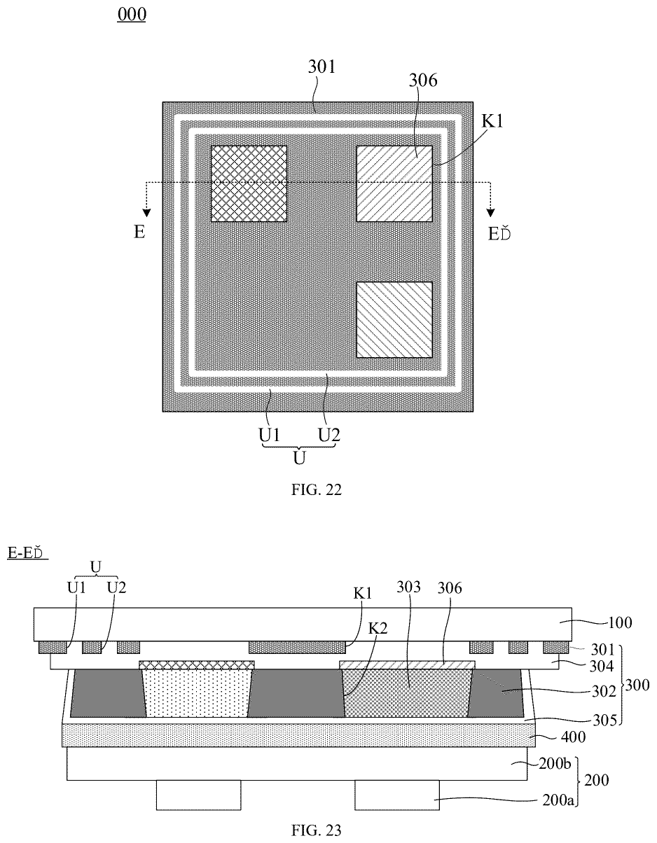

In the embodiments of the present disclosure, referring to FIG. 22, FIG. 22 is a top view of a chip structure provided in yet another embodiment of the present disclosure. A light-shielding layer 301 in a color conversion unit 300 in the chip structure 000 may have at least one annular through groove U. Orthographic projections of the plurality of light-through holes K1 in the light-shielding layer 301 are disposed in a region enclosed by an orthographic projection of the annular through groove U on the first substrate 100. Therefore, the orthographic projections of the plurality of filtering units in the filtering layer 306 within the color conversion unit 300 on the first substrate 100 may also all be disposed in the region enclosed by the orthographic projection of the annular through groove U on the first substrate 100. A portion of the first encapsulation layer 304 in the color conversion unit 300 may be disposed within the annular through groove U. Specifically, the first encapsulation layer 304 disposed in the region enclosed by the annular through groove U is in contact with the first substrate 100. In this case, the portion of the first encapsulation layer 304 distributed in the annular through groove U is a blocking dam, which can block water and oxygen intruding from the edges of the light-shielding layer 301 in a direction parallel to the first substrate 100, and thus can ensure that water and oxygen does not intrude into an inner region of the light-shielding layer 301, thereby further reducing the probability of water and oxygen in the external environment eroding the optical functional layer 303.

In addition, by having a portion of the first encapsulation layer 304 disposed in the annular through groove U, it can also be ensured that during the cutting process to obtain the chip structure 000, the microcracks generated within the first substrate 100 or the first encapsulation layer 304 are blocked by the blocking dams disposed within the annular through groove U, such that the microcracks do not spread to the inner region of the light-shielding layer 301, and thus the product yield of the chip structure 000 obtained by the cutting process can be improved.

It should be noted that since the above embodiments are all illustrated as examples in which none of the light-shielding layer 301 in the film layer structure of the color conversion unit 300 includes the annular through groove U, the structures and the positions distributed of the first encapsulation layer 304 in the color conversion unit 300 are various. Therefore, the embodiments of the present disclosure will schematically describe the film layer structure of the color conversion unit 300 in which the light-shielding layer 301 having the annular through groove U is disposed in the following three exemplary implementations.

For a first exemplary implementation, referring to FIG. 23, FIG. 23 is a schematic diagram of a film layer structure at E-E′ of the chip structure illustrated in FIG. 22. In the case that the first encapsulation layer 304 in the color conversion unit 300 is a film layer structure provided as a whole layer on the first substrate 100, and the filtering layer 306 in the color conversion unit 300 is disposed on a side of the first encapsulation layer 304 facing away from the first substrate 100, a portion of the first encapsulation layer 304 may extend into both the annular through groove U and the through light hole KI of the light-shielding layer 301.

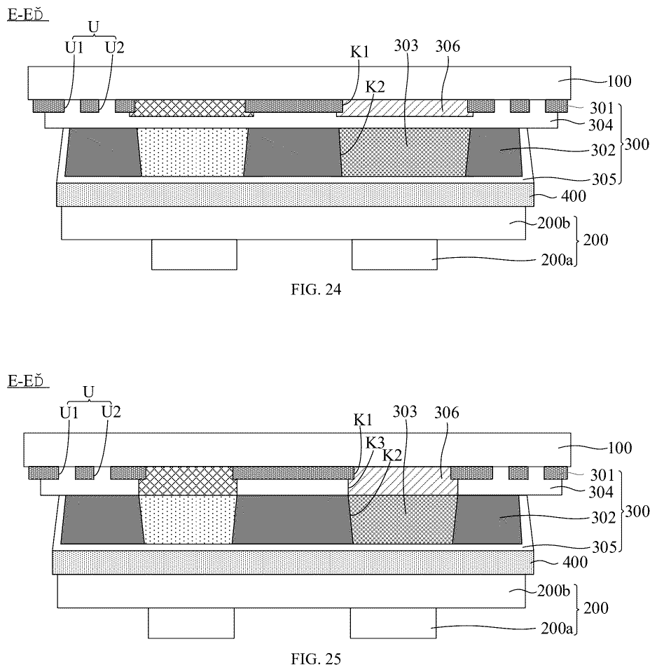

In a second exemplary implementation, referring to FIG. 24, FIG. 24 is a schematic diagram of another film layer structure at E-E′ of the chip structure illustrated in FIG. 22. In the case that the first encapsulation layer 304 in the color conversion unit 300 is a film layer structure provided as a whole layer on the first substrate 100, and the filtering layer 306 in the color conversion unit 300 is disposed on a side of the first encapsulation layer 304 facing the first substrate 100, a portion of the first encapsulation layer 304 may extend into the annular groove U of the light-shielding layer 301, and each filtering unit in the light-filtering layer 306 may extend into the corresponding light-through hole K1 in the light-shielding layer 301.

In a third exemplary implementation, referring to FIG. 25, FIG. 25 is a schematic diagram of yet another film layer structure at E-E′ of the chip structure illustrated in FIG. 22. In the case that the first encapsulation layer 304 in the color conversion unit 300 has the plurality of auxiliary holes K3 in a one-to-one correspondence with the plurality of light-through holes K1 in the light-shielding layer 301, each filtering unit in the light-filtering layer 306 may extend into the corresponding light-through hole K1 in the light-shielding layer 301. In this case, in order to ensure that the colors of the light emitted from the light-through holes K1 in the light-shielding layer 301 are purer, it is necessary to allow the orthographic projection of each auxiliary hole K3 on the first substrate 100 to cover the orthographic projection of the corresponding light-through hole K1 on the first substrate 100, thereby ensuring that the orthographic projection of each filtering unit in the filtering layer 306 on the first substrate 100 can cover the orthographic projection of the corresponding light-through hole K1 on the first substrate 100 in the light-shielding layer 301. That is, a portion of the filtering units in the filtering layer 306 may extend into the corresponding light-through hole K1 in the light-shielding layer 301, while another portion may be disposed outside the corresponding light-through hole K1. In this way, it can be ensured that the light emitted from the optical function layer 303 distributed in the opening region K2 of the defining dam layer 302 can all be filtered by the corresponding filtering unit in the filtering layer 306 after being emitted to the corresponding light-through hole K1 in the light-shielding layer 301.

In the embodiments of the present disclosure, the orthographic projection of the annular through groove U on the first substrate 100 may be disposed in the orthographic projection of the defining dam layer 302 on the first substrate 100. Preferably, the orthographic projection of the annular through groove U on the first substrate 100 may be disposed in an orthographic projection of the side of the defining dam layer 302 facing the first substrate 100 on the first substrate 100.

In this case, as the intersection line between the orthographic projection of the body portion 3011 in the light-shielding layer 301 and the orthographic projection of the extension portion 3012 in the light-shielding layer 301 on the first substrate 100 is the outer contour of the orthographic projection of the defining dam layer 302 on the first substrate 100. Thus, in the case that the orthographic projection of the annular through groove U on the first substrate 100 is disposed in the orthographic projection of the defining dam layer 302 on the first substrate 100, it can be ensured that the annular through groove U is distributed only in the body portion 3011 in the light-shielding layer 301 and not in the extension portion 3012 in the light-shielding layer 301. In this way, it can be ensured that, on the premise that the annular through grooves U can be normally provided in the light-shielding layer 301, the light emitted from the edges of the second semiconductor layer can be normally absorbed by the extension portion 3012 in the light-shielding layer 301 after the light waveguide phenomenon has been generated inside the second semiconductor layer.

Optionally, as illustrated in FIGS. 22 to 25, in the case that the light-shielding layer 301 in the color conversion unit 300 has a plurality of annular through grooves U, the plurality of annular through grooves U may be sequentially nested and distributed. It is to be noted that the embodiments of the present disclosure are schematically illustrated with two annular through grooves U distributed in the light-shielding layer 301 as an example.

Exemplarily, assuming that, the two annular through grooves U are an annular through groove U1 and an annular through groove U2, and an area of a region enclosed by the annular through groove U1 is larger than an area of a region enclosed by the annular through groove U2. Then, the orthographic projection of the filtering layer 306 in the color conversion unit 300 on the first substrate 100 may be disposed in an region enclosed by an orthographic projection of the annular through groove U2 on the first substrate 100, and an orthographic projection of the annular through groove U2 on the first substrate 100 may be disposed in the region enclosed by the orthographic projection of the annular through groove U1 on the first substrate 100.

In this case, in the case that the light-shielding layer 300 includes a plurality of annular through grooves U that are nested, as a portion of the first encapsulation layer 304 may extend into each annular through groove U, and the portion of the first encapsulation layer 304 extending into the annular through groove U can act as blocking dams, and thus it is equivalent that a plurality of blocking dams sequentially nested and distributed are arranged in an edge region of the light-shielding layer 300. The water and oxygen intrusion from the edge of the light-shielding layer 301 can be further blocked in a direction parallel to the first substrate 100 by the blocking dams sequentially nested and distributed.

In the embodiments of the present disclosure, in the case that the light-shielding layer 300 includes a plurality of annular through grooves U that are nested, a width of each annular through groove U may be in the range of 3 μm to 5 μm, a distance between two adjacent annular through grooves U (e.g., the annular through groove Ul and the annular through groove U2) is in the range of 3 μm to 5 μm, and a distance between an annular through groove (e.g., the annular through groove U1) of the plurality of annular through grooves U closest to the outer contour of the first substrate 100 and the outer contour of the first substrate 100 is in a range of 5 μm to 15 μm.

In the embodiments of the present disclosure, as illustrated in FIGS. 19 to 25, as the second encapsulation layer 305 in the color conversion unit 300 may be disposed on the side of the defining dam layer 302 and the optical function layer 303 facing away from the first substrate 100, and the color conversion unit 300 in the chip structure 000 is distributed between the first substrate 100 and the light-emitting unit 200, the light-emitting unit 200 in the chip structure 000 may be disposed on the side of the second encapsulation layer 305 facing away from the first substrate 100.

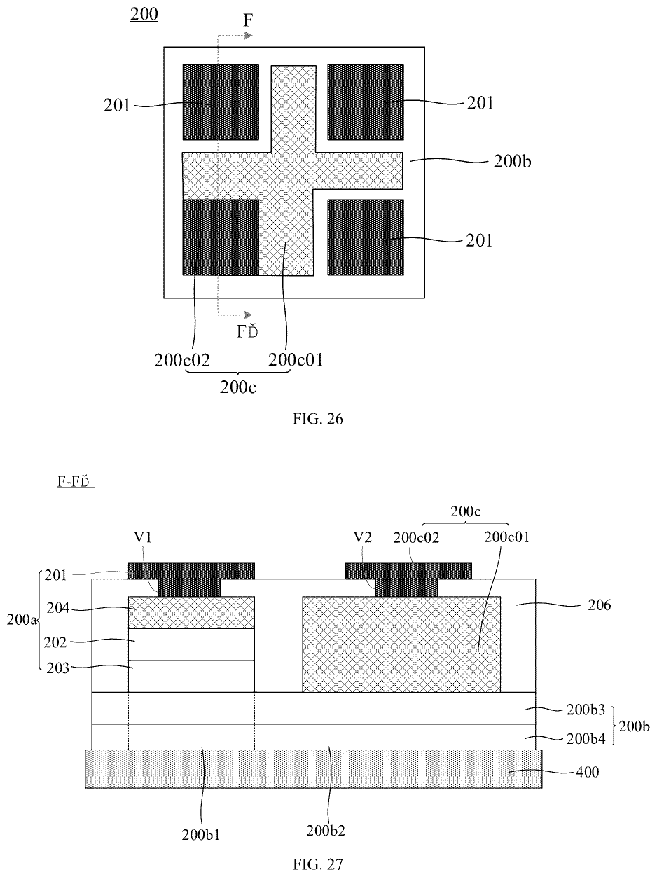

In the embodiments of the present disclosure, referring to FIG. 26 and FIG. 27, FIG. 26 is a top view of a light-emitting unit disposed on a connection layer provided in some embodiments of the present disclosure, and FIG. 27 is a schematic diagram of a film layer structure of the light-emitting unit at F-F′ illustrated in FIG. 26. Each sub-light-emitting function layer 200a in the light-emitting unit 200 may include a first electrode 201, a first semiconductor layer 202, and a light-emitting layer 203 stacked along a direction perpendicular to and facing the first substrate 100.

As the second semiconductor layer 200b in the light-emitting unit 200 is disposed on the light-out side of each sub-light-emitting function layer 200a, and the second semiconductor layer 200b is closer to the first substrate 100 than each sub-light-emitting function layer 200a, the second semiconductor layer 200b may be in contact with a side of the light-emitting layer 203 in each sub-light-emitting function layer 200a facing away from the first semiconductor layer 202.

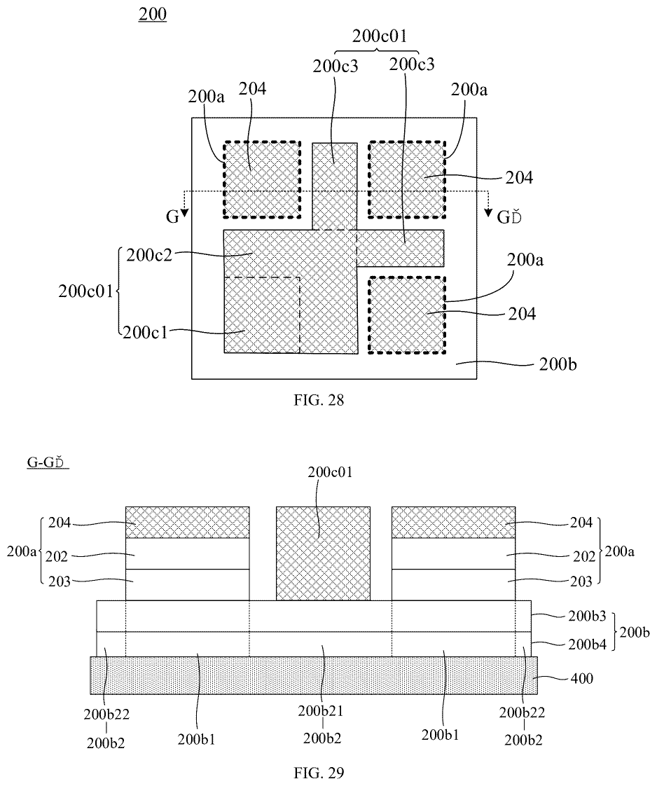

In the embodiments of the present disclosure, referreing to FIG. 28 and FIG. 29, FIG. 28 is a top view of another light-emitting unit disposed on a connection layer provided in some embodiments of the present disclosure, and FIG. 29 is a schematic diagram of a film layer structure of the light-emitting unit at G-G′ illustrated in FIG. 28. The second semiconductor layer 200b may include a connection portion 200b1 and an auxiliary portion 200b2 arranged in a direction parallel to the first substrate 100, where the number of connection portions 200bl in the second semiconductor layer 200b is a plurality, and the plurality of connection portions 200b1 may be in a one-to-one correspondence with a plurality of sub-light-emitting function layers 200a, and each of the connection portions 200b1 may be connected to a corresponding sub light-emitting function layer 200a. For example, each connection portion 200b1 may be connected to a side of the light-emitting layer 203 in the corresponding sub-light-emitting function layer 200a facing away from the first semiconductor layer 202. The auxiliary portion 200b2 in the second semiconductor layer 200b may enable the plurality of connection portions 200b1 to be connected.

It is noted that the portion of the second semiconductor layer 200b other than the portion between the plurality of connection portions 200b1 may all be an auxiliary portion 200b2. For example, the auxiliary portion 200b2 includes a first auxiliary portion 200b21 and a second auxiliary portion 200b22, where the first auxiliary portion 200b21 is disposed between the adjacent connection portions 200b1 and the second auxiliary portion 200b22 surrounds the first auxiliary portion 200b21 and is as a whole with the connection portions 200b1. Specifically, the connection portion 200b1 and the auxiliary portion 200b2 are of the same material and are of one-piece structure. In the above embodiments, the light emitted by each sub-light-emitting function layer 200a is emitted to the second semiconductor layer 200b, is prone to generate a light waveguide inside the second semiconductor layer, and emits from the edges of the second semiconductor layer 200b. The light emitted from the edges of the second semiconductor layer 200b can be absorbed by the extension portion 3012 in the light-shielding layer 301, such that the light leakage phenomenon of the chip structure 000 can be reduced or avoided.

In the present disclosure, the light emitting unit 200 may further include a common electrode layer 200c. The common electrode layer 200c may be connected to the auxiliary portion 200b2 in the second semiconductor layer 200b.

Optionally, in the light-emitting unit 200, the material of the first semiconductor layer 202 in each sub-light-emitting function layer 200a may include a P-type doped gallium nitride. The light-emitting layer 203 in each sub-light-emitting function layer 200a may be a multi-quantum well layer. The second semiconductor layer 200b may include a first sub-layer 200b3 and a second sub-layer 200b4 stacked along a direction perpendicular to and facing the first substrate 100, i.e., the first sub-layer 200b3 is closer to the sub-light-emitting function layer 200a with respect to the second sub-layer 200b4, i.e., the first sub-layer 200b3 may be disposed between the second sub-layer 200b4 and the light-emitting layer 203 in the sub-light-emitting function layer 200a. The material of the first sub-layer 200b3 in the second semiconductor layer 200b may be N-type doped gallium nitride, and the second sublayer 200b4 in the second semiconductor layer 200b may be a gallium nitride buffer layer.

In this case, in the light-emitting unit 200, in the case that the first electrode 201 in a certain sub-light-emitting functional layer 200a is loaded with an anode signal after the cathode signal is loaded in the common electrode layer 200c, the light-emitting layer 203 in the sub-light-emitting function layer 200a may emit the first light.

In some embodiments of the present disclosure, each sub-light-emitting function layer 200a in the light-emitting unit 200 may further include a current spreading layer 204 disposed between the first electrode 201 and the first semiconductor layer 202. One side of the current spreading layer 204 in each sub-light-emitting function layer 200a may be in contact with the first semiconductor layer 202, and the other side may be electrically connected to the first electrode 201. Optionally, the material of the current spreading layer 204 is an indium tin oxide (ITO), and the provision of the current spreading layer 204 in the sub-light-emitting function layer 200a facilitates the transmission of holes and improves the electrical performance of the chip structure 000.

In the present disclosure, the common electrode layer 200c in the light-emitting unit 200 may include a first common electrode layer 200c01 that is provided in contact with the second semiconductor 200b, and a second common electrode layer 200c02 that is electrically connected to the side of the first common electrode layer 200c01 facing away from the second semiconductor 200b. The second common electrode layer 200c02 may be provided in the same layer and with the same material as the first electrode 201 in each sub-light-emitting function layer 200a, i.e., the second common electrode layer 200c02 and each first electrode 201 are formed by using the same composition process.

In the embodiments of the present disclosure, the light-emitting unit 200 may further include an insulating protective layer 206 disposed on a side of the first common electrode layer 200c01 and each sub-light-emitting function layer 200a facing away from the second semiconductor layer 200b. The insulating protective layer 206 may have a plurality of first connection holes VI disposed in a one-to-one correspondence with the plurality of sub-light-emitting function layers 200a and a second connection hole V2 disposed correspondingly with the first common electrode layer 200c01. 200c01. The plurality of first connection holes V1 may also be in a one-to-one correspondence with the plurality of first electrodes 201, and each of the first electrodes 201 may be electrically connected to the current spreading layer 204 in the corresponding sub-light-emitting function layer 200a through the corresponding first connection hole V1. The second connection hole V2 may correspond to the second common electrode layer 200c02, and the second common electrode layer 200c02 may be electrically connected to the first common electrode layer 200c01 in the common electrode layer 200c through the second connection hole V2. It should be noted that for ease of viewing the insulating protective layer 206 is illustrated in the light-emitting unit illustrated in FIG. 26, the insulating protective layer 206 is not illustrated in the light-emitting unit illustrated in FIG. 28.

For example, the first common electrode layer 200c01 may act as a current extension.

For example, the material of both the first common electrode layer 200c01 and the second common electrode layer 200c02 is metal.

Optionally, a thickness of the first common electrode layer 200c01 may be much greater than a thickness of the current spreading layer 204. For example, the thickness of the first common electrode layer 200c01 may be equal to the thickness of the sub-light-emitting function layer 200a. That is, a surface of the first common electrode layer 200c01 facing away from the second semiconductor layer 200b may be flush with a surface of the current spreading layer 204 facing away from the second semiconductor layer 200b. In this way, the sides of the first electrode 201 and the second common electrode layer 200c02 in the light-emitting unit 200 facing away from the connection layer 400 are also flush. As the first electrode 201 and the second common electrode layer 200c02 in the chip structure 000 need to be soldered to the driving backplane in the case that the chip structure 000 is subsequently attached to the driving backplane. Therefore, in the chip structure 000, in the case that the first electrode 201 and the second common electrode layer 200c02 are flush on a side of the first electrode 201 and the second common electrode layer 200c02 facing away from the connection layer 400, it can be ensured that the chip structure 000 can be stably fixed to the driving backplane.

In the embodiments of the present disclosure, the first common electrode layer 200c01 may include a common electrode body portion 200c1, a first support portion 200c2 fixedly connected to the common electrode body portion 200c1, and two second support portions 200c3 fixedly connected to the first support portion 200c2. The common electrode body portion 200c1 may be electrically connected to the second common electrode layer 200c02, the first support portion 200c2 may be distributed at a periphery of the common electrode body portion 200c1, and each of the second support portions 200c3 may be distributed on a side of the first support portion 200c2 facing away from the common electrode body portion 200c1. In the two second support portions 200c3, one second support portion 200c3 may be distributed between a first pixel light-emitting function layer 200a1 and a second pixel light-emitting function layer 200a2 in a row direction, and the other second support portion 200c3 may be distributed between the second pixel light-emitting function layer 200a2 and a third pixel light-emitting function layer 200a3 in the column direction. In this way, both a higher intensity of the entire light-emitting unit 200 and a larger volume of the common electrode layer 200c can be ensured, thereby reducing the resistance in the light-emitting unit 200 for transmitting a common cathode signal.

In summary, the embodiments of the present disclosure provide a chip structure including: a first substrate, a light-emitting unit, and a color conversion unit. The light-shielding layer in the color conversion unit may include a body portion, and an extension portion surrounding the body portion. After the light emitted from each sub-light-emitting function layer in the light-emitting unit is emitted to a second semiconductor layer, and the light is generated inside the second semiconductor layer by an optical waveguide phenomenon, the light emitted from the edges of the second semiconductor layer can be absorbed by the extension portion in the light-shielding layer, thereby reducing the probability of light leakage phenomena occurring in the chip structure, and making a better display effect of the display panel integrated with the chip structure. Also, as the first encapsulation layer is provided between the light-shielding layer and the defining dam layer, the first encapsulation layer can cover the body portion in the light-shielding layer, and the body portion in the light-shielding layer is overlapped with the orthographic projection of the defining dam layer on the first substrate, after intruding into the light-shielding layer, water and oxygen intruding into the interior of the light-shielding layer can be isolated by the first encapsulation layer, such that water and oxygen do not intrude into the defining dam layer again, and thus it can be ensured that water and oxygen intruding into the light-shielding layer do not erode the optical function layer, thereby further improving the reliability of the optical function layer, and further improving the stability of the chip structure.

The embodiments of the present disclosure also provide a display panel. The display panel may be a display screen in a mobile phone, a laptop or a flat computer, or an outdoor advertising screen. The display panel may include a driving backplane, and a plurality of chip structures disposed on a side of the driving backplane. Each chip structure in the display panel may be the chip structure in the above embodiments. Also, each anode pad and each cathode pad in the chip structure may be fixed to the driving backplane by welding to be electrically connected to the driving backplane. It is to be noted that the driving backplane can provide corresponding driving signals to each chip structure, such that the light-emitting units in the chip structure emit light, and thus the display panel can present a corresponding display screen.

It should be noted that in the accompanying drawings, the sizes of the layers and regions may be exaggerated for the sake of clarity of the illustrations. Moreover, it is understood that in the case that an element or layer is referred to as being “on” another element or layer, it may be directly on the other element, or intermediate layers may exit. Also, it is to be understood that in the case that the element or layer is referred to as being “under” another element or layer, it may be directly under the other element, or more than one intermediate layer or element may exist. It is also understood that in the case that a layer or element is referred to as being “between” two layers or elements, it may be the only layer between the two layers or elements, or more than one intermediate layer or element may also exist. Similar reference marks throughout indicate similar elements.

In the present disclosure, the terms “first” and “second” are used for descriptive purposes only and are not to be understood as indicating or implying relative importance. The term “plurality” refers to two or more, unless otherwise expressly limited.

The foregoing are only optional embodiments of the present disclosure and are not intended to limit the present disclosure, and any modifications, equivalent substitutions, improvements, etc. made within the spirit and principles of the present disclosure shall be included in the scope of protection of this application.

What is claimed is:

1. A chip structure, comprising: a first substrate, a light-emitting unit and a color conversion unit, wherein the color conversion unit is disposed on a light-out side of the light-emitting unit and comprises:
a light-shielding layer disposed on a side of the first substrate, wherein the light-shielding layer comprises a body portion and an extension portion surrounding the body portion, and the body portion has a plurality of light-through holes;
a defining dam layer disposed on a side of the light-shielding layer facing away from the first substrate, wherein the defining dam layer has a plurality of opening regions in a one-to-one correspondence with the plurality of light-through holes, an orthographic projection of each of the plurality of opening regions on the first substrate is overlapped with an orthographic projection of a corresponding light-through hole on the first substrate, and an orthographic projection of the body portion on the first substrate is overlapped with an orthographic projection of the defining dam layer on the first substrate, and the extension portion protrudes from an outer contour of the defining dam layer in a direction parallel to the first substrate;
a first encapsulation layer disposed between the light-shielding layer and the defining dam layer, wherein the first encapsulation layer covers the body portion and covers at least a portion of the extension portion;
an optical function layer disposed in each of the plurality of opening regions, wherein at least a portion of the optical function layer is configured to convert a color of light entering the optical function layer; and
a second encapsulation layer disposed on a side of the defining dam layer facing away from the first substrate, wherein the second encapsulation layer has a first contact region in contact with the first encapsulation layer and the first contact region is disposed around the defining dam layer.

2. The chip structure according to claim 1, wherein the first contact region has a shape of an annulus and the annulus has a width in a range of 0.5 μm to 60 μm; and
a shape enclosed by an outer contour of the first substrate is a rectangle, and a length and a width of the rectangle are less than or equal to 500 μm.

3. The chip structure according to claim 1, wherein a distance between an outer contour of the light-shielding layer and an outer contour of the first substrate is less than or equal to 20 μm in the direction parallel to the first substrate.

4. The chip structure according to claim 1, wherein an outer contour of the first substrate is flush with an outer contour of the light-shielding layer.

5. The chip structure according to claim 3, wherein the first substrate has a first side edge and a second side edge disposed opposite to each other;
in the direction parallel to the first substrate, a distance between a part of an outer contours, which is adjacent to the first side edge, of the light-shielding layer and the first side edge is a first distance, and a distance between another part of the outer contour, which is adjacent to the second side edge, of the light-shielding layer and the second side edge a second distance; and
a sum of the first distance and the second distance is greater than or equal to 5 μm.

6. The chip structure according to claim 1, wherein an outer contour of at least one of the first encapsulation layer and the second encapsulation layer is flush with an outer contour of the first substrate.

7. The chip structure according to claim 1, wherein a distance is present between an outer contour of at least one of the first encapsulation layer and the second encapsulation layer and an outer contour of the first substrate.

8. The chip structure according to claim 1, wherein an outer side surface of the first substrate is a fracture surface, and the fracture surface comprises a first fracture portion, a second fracture portion and a laser cutting portion disposed between the first fracture portion and the second fracture portion;
wherein the first fracture portion and the second fracture portion present traces of applied stress fracture, and the laser cutting portion presents ablation traces of laser cutting.

9. The chip structure according to claim 1, wherein the color conversion unit further comprises a filtering layer disposed between the first substrate and the optical function layer, the filtering layer comprises a plurality of filtering units in a one-to-one correspondence with the plurality of light-through holes, and an orthographic projection of each of the plurality of filtering units on the first substrate is overlapped with an orthographic projection of a corresponding light-through hole on the first substrate.

10. The chip structure according to claim 9, wherein an orthographic projection of the optical function layer on the first substrate and the orthographic projection of the defining dam layer on the first substrate are both disposed in an orthographic projection of the first encapsulation layer on the first substrate;
the light-filtering unit is disposed on a side of the first encapsulation layer facing away from the first substrate and a portion of the first encapsulation layer is disposed in each of the plurality of light-through holes, or
the light-filtering unit is disposed on a side of the first encapsulation layer facing the first substrate and at least a portion of the light-filtering layer is disposed in each of the plurality of light-through holes.

11. The chip structure according to claim 9, wherein the first encapsulation layer has a plurality of auxiliary holes in a one-to-one correspondence with the plurality of light-through holes, and an orthographic projection of each of the plurality of auxiliary holes on the first substrate is overlapped with an orthographic projection of each of the corresponding light-through holes on the first substrate;
at least a portion of the light-filtering unit is disposed in each of the plurality of auxiliary holes, and two opposite surfaces of the light-filtering unit are in contact with the first substrate and the optical function layer, respectively.

12. The chip structure according to claim 11, wherein the orthographic projection of each of the plurality of auxiliary holes on the first substrate is in the orthographic projection of each of the corresponding light-through holes on the first substrate, and a portion of the first encapsulation layer extends into the light-through holes and covers an inner wall of the light-through hole, such that the light-filtering unit is spaced apart from the light-shielding layer.

13. The chip structure according to claim 1, wherein the light-shielding layer has at least one annular through groove, and orthographic projections of the plurality of light-through holes on the first substrate are disposed in a region enclosed by an orthographic projection of the annular through groove on the first substrate; and
a portion of the first encapsulation layer is disposed in the annular through groove.

14. The chip structure according to claim 13, wherein the orthographic projection of the annular through groove on the first substrate is in the orthographic projection of the defining dam layer on the first substrate.

15. The chip structure according to claim 1, wherein the second encapsulation layer covers a surface of the defining dam layer facing away from the first substrate and a surface of the optical function layer facing away from the first substrate and covers an outer side of the defining dam layer; and the light-emitting unit is disposed on a side of the second encapsulation layer facing away from the first substrate; and
the orthographic projection of the defining dam layer on the first substrate and the orthographic projection of the optical function layer on the first substrate are both disposed in an orthographic projection of the second encapsulation layer on the first substrate.

16. (canceled)

17. The chip structure according to claim 1, further comprising a connection layer disposed on a side of the second encapsulation layer facing away from the first substrate, wherein the light-emitting unit is disposed on a side of the connection layer facing away from the first substrate, and the light-emitting unit is fixed to the side of the second encapsulation layer facing away from the first substrate through the connection layer.

18. The chip structure according to claim 17, wherein the light-emitting unit comprises a plurality of sub-light-emitting function layers in a one-to-one correspondence with the plurality of opening regions, and an orthographic projection of each of the plurality of sub-light-emitting function layers on the first substrate is overlapped with an orthographic projection of a corresponding opening region on the first substrate.

19. The chip structure according to claim 18, wherein the plurality of sub-light-emitting function layers comprise a first sub-light-emitting function layer, a second sub-light-emitting function layer and a third sub-light-emitting function layer, the plurality of sub-light-emitting function layers emit a first light in an operating state, and the first light comprises at least one of blue light and ultraviolet light;
the plurality of opening regions comprises a first opening region, a second opening region and a third opening region, wherein the first opening region is disposed corresponding to the first sub-light-emitting function layer, the second opening region is disposed corresponding to the second sub-light-emitting function layer, and the third opening region is disposed corresponding to the third sub-light-emitting function layer; and
the optical function layer comprises a first color conversion section for converting the first light into red light, a second color conversion section for converting the first light into green light, and a third color conversion section for converting the first light into blue light or maintaining blue light; wherein the first color conversion section is disposed in the first opening region, the second color conversion section is disposed in the second opening region, and the third color conversion section is disposed in the third opening region.

20. The chip structure according to claim 19, wherein each of the plurality of sub-light-emitting function layers comprises a first electrode, a first semiconductor layer and a light-emitting layer stacked in a direction perpendicular to and facing the first substrate;
the light-emitting unit further comprises a second semiconductor layer and a common electrode layer, and the second semiconductor layer is disposed on a light-out side of each of the plurality of sub-light-emitting function layers;
the second semiconductor layer comprises connection portions and auxiliary portions arranged in the direction parallel to the first substrate, wherein the connection portions are connected to the sub-light-emitting function layers, the auxiliary portions make the connection portions connect to each other, the connection portion and the auxiliary portion are integrated, and the common electrode layer is connected to the auxiliary portions; and
wherein a material of the first semiconductor layer comprises P-type doped gallium nitride, and the light-emitting layer is a multi-quantum well layer; and
the second semiconductor layer comprises a first sub-layer and a second sub-layer stacked along a direction perpendicular and facing the first substrate, wherein the first sub-layer is disposed between the second sub-layer and the light-emitting layer, a material of the first sub-layer is N-type doped gallium nitride, and the second sub-layer is a gallium nitride buffer layer.

21. (canceled)

22. (canceled)

23. A display panel, comprising a driving backplane, and a plurality of chip structures in an array on a side of the driving backplane, wherein each of the plurality of the chip structures is the chip structure as defined in claim 1.
